(19) United States
(12) Patent Application Publication
(10) Pub. No.: US 2010/0177155 A1
(43) Pub. Date: Jul. 15, 2010

(54) Light Emitting Element Array, Light Emitting Device, and Image Forming Apparatus

(75) Inventor: Hironori Kii, Kyoto (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/666,783

(22) PCT Filed: Mar. 31, 2008
(86) PCT No.: PCT/JP2008/056382

§ 371 Date: Dec. 24, 2009

(30) Foreign Application Priority Data
Jun. 25, 2007 (JP) 2007-165839
Nov. 30, 2007 (JP) 2007-311672

(51) Int. Cl. B41J 2/435; F21V 23/04; H01L 33/00

(52) U.S. Cl. 347/224; 315/51; 257/88; 257/E33.044

(57) ABSTRACT

Provided are a light emitting element array that can perform a time-division driving operation with a small number of driving ICs and a small-sized light emitting device employing the light emitting element array and an image forming apparatus having the light emitting device. A light emitting element array chip (1) includes n pieces of switch thyristors (S) (n is an integer of 2 or more), n pieces of horizontal gate lines (GH) respectively connected to N gate electrodes of the n pieces of switch thyristors (S), a plurality of light emitting thyristors (T) whose N gate electrodes (b) each is connected to any one of the n horizontal gate lines (GH). One ends of CS resistors (RCS) are connected to the N gate electrodes (d) of the n pieces of switch thyristors (S), and the another ends of the CS resistors (RCS) are connected to a common selection signal input terminal (CS). It is possible to realize time-division driving operation in which a light emission signal and a gate signal are shared between the plurality of light emitting element arrays by allowing only the light emitting element array to which a low level selection signal is inputted and which is in a selected state to emit light.

### TECHNICAL FIELD

The present invention relates to a light emitting element array including a plurality of light emitting elements, a light emitting device having the light emitting element array, and an image forming apparatus having the light emitting device.

### BACKGROUND ART

There has been known an LED array having a plurality of light emitting diodes (abbreviated as LED) arranged therein as a light emitting device which is applied to an optical printer head of an electrophotographic printer. The LED array includes a plurality of bonding pads to individually connect the light emitting diodes to a driving circuit. For example, in the case where an electrophotographic printer is configured with the specification of A3 size and 600 dpi (dot per inch) and anodes or cathodes of the LEDs are made to be a common electrode realized by a conductive substrate, the same number of connecting portions between bonding pads and circuit wiring lines as the number of light emitting elements is required, which amounts to about 7,300 portions. Accordingly, a very long time is required for bonding the both by a wire bonding method, which makes it difficult to improve the productivity. Furthermore, a larger area than that required for forming the light emitting elements is required to form the bonding pads and the number of light emitting elements per unit length in the scanning direction increases as an image to be formed by the electrophotographic printer increases in precision, which causes an increase of the number of bonding pads and an increased size of the apparatus.

There is known as a first conventional technique for reducing the number of bonding pads, a light emitting element array employing a dynamic (time-division) driving scheme. In the first conventional technique, an LED array is divided into n₁ groups including m₁ pieces of LEDs (wherein n₁ is a positive integer and m₁ is a positive integer), the anodes or cathodes of the LEDs of the groups are formed as a common electrode, and m₁×n₁ matrix wiring lines are made thereon. In a dynamic (time-division) driving operation, a driving signal applied to the matrix wiring lines is time-divisionally switched to allow the LEDs to emit light. By using the dynamic driving LED array, the number of bonding pads can be reduced to about ¼, compared with the above-mentioned LED array in which the LEDs are connected to the driving circuits, respectively (for example, Japanese Unexamined Patent Publication JP-A 11-268333 (1999)).

There is known as a second conventional technique, a dynamic driving light emitting device for driving a light emitting element array in which field effect transistors are connected to the LEDs, respectively by a driving IC (Integrated Circuit) having switching elements built therein (for example, see Japanese Unexamined Patent Publication JP-A 6-177431 (1994)). In the light emitting device, a driving IC (Integrated Circuit) having switching elements such as NAND gates built therein is connected to the light emitting element array, the switching elements built in the driving IC calculate a logical product of a strobe signal (STB) and a gate signal, and the gate signal is outputted only when the strobe signal has a true value, whereby the light emitting element array can be driven dynamically.

There is known as a third conventional technique, in order to reduce the occupied area of the wiring lines connected to the light emitting elements, a light emitting element array in which a light emission thyristor having a PNPN structure is used as the light emitting element, ones of the anodes and the cathodes are formed of a conductive substrate in common, and the other of the anodes and the cathodes is connected to the gate electrodes in a matrix (for example, see Japanese Unexamined Patent Publication JP-A 3-194978 (1991) and Japanese Unexamined Patent Publication JP-A 2001-217457). By connecting the gate electrodes, in which current hardly flows, all over the light emitting element array by the use of electrode wiring lines, it is possible to reduce the line width of the electrode wiring lines and to reduce the area required for forming the electrode wiring lines.

However, in the first conventional technique, since m₁+n₁ pieces of electrode wiring lines are connected to the anodes or cathodes of the LEDs, when the LEDs are emitted, main current proportional to the light emission intensity of the LEDs flows in any electrode wiring line. In this case, when the wiring line resistance is high, the power consumption of the driving IC is enhanced or the driving performance is deteriorated due to the wiring line resistance loss. Accordingly, the line width needs to be enhanced to some extent to reduce the wiring line resistance. Therefore, there is a problem in that the area required for forming the electrode wiring lines increases and the surface area of a chip having the LED array formed therein also increases.

In the first to third conventional techniques, for example, when the dynamic (time-division) driving operation is performed using the m₁×n₁ matrix wiring lines, m₁+n₁ pieces of electrode wiring lines are required for one light emitting element array. However, when a light emitting device is configured to include a plurality of p₁ pieces of light emitting element arrays (wherein p₁ is an integer of 2 or more), p₁×(m₁+n₁) pieces of electrode wiring lines proportional to the number of light emitting element arrays are required. The number of output terminals of the driving IC to drive the light emitting element arrays needs to be enhanced depending on the number of required electrode wiring lines. When the number of terminals of the driving IC is equal to the number of terminals of one light emitting element array, the driving ICs corresponding to the number of light emitting element arrays are required. In this way, when the light emitting device is configured to include the plurality of light emitting element arrays, a lot of driving ICs are required for the conventional techniques and the number of wiring lines to connect the light emitting element arrays to the driving ICs is enhanced, thereby complicating the device or enlarging the device.

Further, in the second conventional technique, the driving IC having the switching elements such as NAND gates built therein needs to be connected to the light emitting element array. When a light emitting device is configured to include the plurality of light emitting element arrays, the number of driving ICs connected to the light emitting element arrays increases with the increase of the number of light emitting element arrays, thereby complicating or enlarging the device as a whole.

### DISCLOSURE OF INVENTION

Accordingly, an object of the invention is to provide a light emitting element array that can perform a time-division driving operation with a small number of driving ICs and to provide a small-sized light emitting device employing the light emitting element array and an image forming apparatus having the light emitting device.

The invention is directed to a light emitting element array, comprising:

(a) n pieces of switching elements (n is an integer of 2 or more) each comprising a first electrode, a second electrode, and a first control electrode that outputs a control signal when a first signal is inputted into the first electrode and a second signal is inputted into the second electrode;

(b) n pieces of signal transmission lines respectively connected to the first control electrodes; and

(c) a plurality of light emitting elements that each comprises a third electrode, and a second control electrode connected to any one of the n pieces of signal transmission lines, and that each emits light when a third signal is inputted into the third electrode and the control signal is inputted into the second control electrode; wherein

each of the n pieces of signal transmission lines is connected to the second control electrode of at least one of the plurality of light emitting elements,

the first electrodes of the n pieces of switching elements are electrically connected to each other,

the n pieces of switching elements and the plurality of light emitting elements each comprises a light emission thyristor having either one of a cathode and an anode thereof as a common electrode, and the n pieces of switching elements each further comprises a first resistor and a second resistor,

(i) when the cathode is the common electrode,
an N gate electrode of the light emission thyristor of each of the n pieces of switching elements is connected to one ends of the first and second resistors,
a positive voltage with reference to the common electrode is applied to another end of the first resistor,
the first electrode is connected to another end of the second resistor,
the second electrode is the anode of the light emission thyristor constituting the switching element,
the third electrode is the anode of the light emission thyristor constituting the light emitting element,
the first control electrode is the N gate electrode of the light emission thyristor constituting the switching element, and
the second control electrode is an N gate electrode of the light emission thyristor constituting the light emitting element, and

(ii) when the anode is the common electrode,
a P gate electrode of the light emission thyristor of each of the n pieces of switching elements is connected to one ends of the first and second resistors,
a negative voltage with reference to the common electrode is applied to another end of the first resistor,
the first electrode is connected to another end of the second resistor,
the second electrode is the cathode of the light emission thyristor of each of the n pieces of switching elements,
the third electrode is the cathode of the light emission thyristor of each of the plurality of light emitting elements,
the first control electrode is the P gate electrode of the light emission thyristor of each of the n pieces of switching elements, and
the second control electrode is a P gate electrode of the light emission thyristor of each of the plurality of light emitting elements.

According to the light emitting element array of the invention, the light emitting element array includes n pieces of switching elements (n is an integer of 2 or more) that output the control signal when both of the first signal and the second signal are inputted, n pieces of signal transmission lines through which the control signal is transmitted, and the plurality of (n or more) light emitting elements that emit light when the control signal from the signal transmission lines and the third signal are inputted. The first electrode of each of the n pieces of switching elements is electrically connected to each other, and, thus, the signal can be applied to all of the n pieces of switching elements in the light emitting element array.

When the first signal is commonly inputted to each of the n pieces of switching elements of the light emitting element array, the control signal is further outputted to each of the n pieces of signal transmission lines connected to each of the n pieces of switching elements to which the second signal is inputted. When the third signal is inputted to each of the plurality of light emitting elements connected to each of the n pieces of signal transmission lines in which the control signal is outputted, each of the plurality of light emitting elements emit light. On the contrary, when the first signal is not commonly inputted to the light emitting element array, each of the n pieces of switching elements does not output the control signal in spite of the input of the second signal. Accordingly, even when the third signal is inputted to each of the plurality of light emitting elements, a light emitting element of the plurality of light emitting elements in which the third signal is inputted does not emit light.

Accordingly, when a light emitting device is configured to include the plurality of light emitting element arrays, a light emitting element belonging to which light emitting element array is to be caused to emit light can be selected according to the first signal. Hereinafter, it is assumed that the light emitting element array to which the first signal is inputted is in a selected state. Accordingly, by sequentially applying the first signal to the light emitting element arrays constituting the light emitting device into the selected state, it is possible to perform a time-division driving operation by using the driving ICs to supply the second signal and the third signal to the light emitting element arrays and the wiring lines between the plurality of light emitting elements and the driving ICs in common to the plurality of light emitting element arrays. In this way, when the light emitting device is configured to include the light emitting element array of the invention, the light emitting element arrays can share the driving ICs and the wiring lines, thereby embodying the light emitting device with the small number of driving ICs and wiring lines.

The switching element can be configured to include a light emission thyristor, the first resistor and the second resistor, and the light emitting element can be configured to include a light emission thyristor. Here, the light emission thyristors of each of the n pieces of switching elements and the plurality of light emitting elements use the cathodes or the anodes as a common electrode (the potential of which is Vg=0 V).

When the cathodes are used as the common electrode, the N-gate electrode of the light emission thyristor in the respective switching elements, one end of the first resistor, and one end of the second resistor are connected. Another end of the first resistor is supplied with a positive voltage using the potential of the cathodes of the common electrode as a reference potential. In this case, another end of the second resistor is connected to the first electrode to which the first signal is inputted, the anode of the light emission thyristor corresponds to the second electrode to which the second signal is inputted, and the N-gate electrode of the light emission thyristor corresponds to the first control electrode to which the control signal is outputted. The light emitting element is formed of a light emission thyristor, the third electrode to which the third signal is inputted corresponds to the anode of the light emission thyristor, and the second control electrode to which the control signal is inputted corresponds to the N-gate electrode of the light emission thyristor.

Hereinafter, an example of the circuit operation according to the above-described circuit configuration will be shown.

As the first signal, a signal at a low level (in which the potential is 0 V) is applied to another end of the second resistor, and a positive voltage applied to another end of the first resistor is taken as Vcc volts. Furthermore, in a state where the first signal is not inputted, a voltage (Vcc volts) at a high level in which the potential is the same as Vcc volts is set to be applied to another end of the second resistor. A divided voltage according to the resistances of the first and the second resistors is applied to the N gate electrode of the light emission thyristor constituting each of the n pieces of switching elements (hereinafter, referred to as a “switch thyristor”), and, thus, Vcc volts are applied in a state where the first signal is not inputted, and a divided voltage (Vd volts) of Vcc volts is applied in a state where the first signal is inputted.

Furthermore, a signal at a high level, is applied as the second signal to the anode of the switch thyristor, and, in a state where the second signal is not inputted, a voltage at a low level (in which the potential is 0 V) is set to be applied to the anode of the switch thyristor. The high level of the second signal is selected to be a value with which, in a state where Vd volts are applied to the N gate of the switch thyristor, when the second signal is inputted, the switch thyristor shifts from an off-state to an on-state. Accordingly, in a state where the first signal is inputted and Vd volts are applied to the N gate of the switch thyristor, when a second signal at a high level is inputted, the switch thyristor shifts to an on-state. When the switch thyristor shifts to an on-state, the N gate electrode of the switch thyristor corresponding to the first control electrode shifts from Vd to approximately 0 V, and approximately 0 V is outputted as a control signal. Furthermore, when the second signal is not inputted and a voltage at a low level is applied to the anode of the switch thyristor, the switch thyristor is kept in an off-state regardless of whether or not the first signal is inputted. That is to say, the switch thyristor functions as an AND circuit that shifts to an on-state and outputs a control signal only when the first and the second signals are inputted.

Furthermore, in the light emission thyristor constituting each of the plurality of light emitting elements (hereinafter, referred to as a “light emitting thyristor”), the current and voltage characteristics, such as a threshold voltage, are the same as those of the switch thyristor. Furthermore, a signal at a high level is applied as the third signal to the anode of the light emitting thyristor, and, in a state where the third signal is not inputted, a voltage at a low level (in which the potential is 0 V) is set to be applied to the anode of the light emitting thyristor. The high level of the third signal is selected to be a value with which, in a state where Vd or Vcc is applied to the N gate electrode of the light emitting thyristor, even when the third signal is inputted, the light emitting thyristor is kept in an off-state, and, in a state where a control signal of approximately 0 V is applied to the N gate electrode of the light emitting thyristor, when the third signal is inputted, the light emitting thyristor shifts to an on-state. Accordingly, in a state where the first and the second signals are inputted and the control signal is inputted into the N gate electrode of the light emitting thyristor, when the third signal is inputted, the light emitting thyristor shifts from an off-state to an on-state and emits light. Furthermore, in a state where at least one of the first and the second signals is not inputted and the control signal is not inputted, the light emitting thyristor is kept in an off-state regardless of whether or not the third signal is inputted. That is to say, the light emitting thyristor emits light only when all of the first, the second, and the third signals are inputted.

Accordingly, according to the invention, a logic circuit allowing the light emitting elements to emit light can be configured with a simple circuit structure employing light emission thyristors without using complex semiconductor devices such as NAND gates or inverters, thereby embodying a light emitting element array with easy design and simple manufacturing processes.

Here, when the anode of the light emission thyristor is used as a common electrode, the above-described logic circuit can be realized in a similar manner by reversing the polarity of the light emission thyristor, reversing the positive and negative of the voltage applied to another end of the first resistor, and reversing the conductivity type of the gate electrode of the light emission thyristor.

Furthermore, in the invention it is preferable that the plurality of light emitting elements comprises a plurality of light emitting element blocks comprising n or less pieces of light emitting elements in which the third electrodes thereof are electrically connected to each other, and

the second control electrodes of the light emitting elements in one of the plurality of light emitting element blocks are connected to respective ones of the n pieces of signal transmission lines which are different with each other.

According to the light emitting element array of the invention, the plurality of light emitting elements comprises the plurality of light emitting element blocks including n or less pieces of light emitting elements, and, in the same light emitting element block, the third electrodes to which the third signal is applied are electrically connected to each other, and, thus, a common third signal is applied to the light emitting elements belonging to the same light emitting element block. Furthermore, in the same light emitting element block, the light emitting elements are respectively connected to different signal transmission lines, and, thus, different control signals are respectively applied. Accordingly, in a state where the light emitting element array is in a selected state due to the first signal, when the second signal is sequentially applied on a time-division basis to the switching elements of that light emitting element array, the control signal is sequentially transmitted also to the signal transmission lines connected to the switching elements, and the control signal is sequentially applied also to the light emitting elements in the same light emitting element block. Thus, when a common third signal is applied to each of the light emitting element blocks according to that timing, time-division driving operation in the light emitting element block can be realized. In this manner, in the invention, the plurality of light emitting element blocks in the same light emitting element array can perform time-division driving operation, and, thus, the number of driving IC output terminals that supply the second signal and the third signals, and the number of wires between the driving ICs and the light emitting element arrays can be reduced, and a small light emitting device in which the number of wires is small can be realized. Furthermore, the number of signal transmission lines in the light emitting element array can be also reduced, and, thus, a small light emitting element array can be realized.

Further, in the invention, it is preferable that the plurality of light emitting elements are arranged in a line,

each of the plurality of light emitting element blocks is composed of n−1 pieces of light emitting elements (n is an integer of 4 or more),

odd-numbered light emitting element blocks of the plurality of light emitting element blocks, which are numbered according to an order of from one end to the other end in an arrangement direction of the plurality of light emitting elements, each comprises an i₁-th light emitting element which is numbered according to the order of from one end to the other end in the arrangement direction, and the i₁-th light emitting element is connected to a j₁-th signal transmission line so as to satisfy i₁=j₁ (wherein i₁ is an integer of 1 or more and n−1 or less and j₁ is an integer of 1 or more and n−1 or less), and

even-numbered light emitting element blocks of the light emitting element blocks, which are numbered according to an order of from one end to the other end in the arrangement direction of the plurality of light emitting elements, each comprises an i₂-th light emitting element which is numbered according to the order of from one end to the other end in the arrangement direction, and the i₂-th light emitting element is connected to a j₂-th signal transmission line so as to satisfy i₂+j₂=n+1 (wherein i₂ is an integer of 1 or more and n−1 or less and j₂ is an integer of 2 or more and n or less).

In the light emitting element array according to the invention, the respective light emitting element blocks include n−1 pieces of light emitting elements smaller by 1 than the number of signal transmission lines (n is an integer of 4 or more 4). Here, in a direction (referred to as an X₁ direction) from one end in the arrangement direction of the light emitting elements to the other end thereof, the light emitting elements of the respective light emitting element blocks are numbered with first to (n−1)-th numbers in the X₁ direction and the n pieces of signal transmission lines are numbered with first to n-th numbers in a predetermined order. According to the configuration, in the odd-numbered light emitting element blocks, the i₁-th light emitting element is connected to the j₁-th signal transmission line so as to satisfy i₁=j₁ (wherein 1≦i₁≦n−1 and 1≦j₁≦n−1). In the even-numbered light emitting element blocks, the i₂-th light emitting element is connected to the j₂-th signal transmission line so as to satisfy i₂+j₂=n+1 (wherein 1≦i₂≦n−1 and 2≦j₂≦n).

In this case, the light emitting element adjacent to the light emitting element connected to the first signal transmission line in the arrangement direction is connected to the second signal transmission line. The light emitting element adjacent to the light emitting element connected to the j₃-th signal transmission line in the arrangement direction (wherein is connected to one of the (j₃−1)-th and (j₃+1)-th signal transmission lines. The light emitting element adjacent to the light emitting element connected to the n-th signal transmission line in the arrangement direction is connected to the (n−1)-th signal transmission line. Accordingly, when the second signal is sequentially inputted to the switching elements in the light emitting element array selected by inputting the first signal and the control signal is time-divisionally sequentially outputted to the first to n-th signal transmission lines, the temporal difference in light emission timing between the adjacent light emitting elements can be reduced. Since the adjacent light emitting elements are not connected to the same signal transmission line, it is possible to prevent the adjacent light emitting elements from concurrently emitting light.

Accordingly, when the light emitting device configured to include the light emitting element, array of the invention is used as an exposure device exposing a photoreceptor drum, the great difference in timing when the adjacent light emitting elements emit light is suppressed, whereby a discontinuous point is not generated at the exposure positions on the photoreceptor drum. Since the concurrent light emission of the adjacent light emitting elements is prevented, the difference in light emission of heat is suppressed when the light emitting elements emit light, thereby making constant the light emission characteristic with the variation in temperature of the light emitting elements. Since the interference of light emitted from the adjacent light emitting elements can be prevented, it is possible to expose the photoreceptor drum with high precision. As a result, in the image forming apparatus employing the light emitting element array of the invention, it is possible to obtain a recorded image with high image quality.

In the light emitting element array of the invention, the light emitting element array comprises a substrate and bonding pads located on one surface of the substrate, wherein

the plurality of light emitting elements are arranged substantially in a straight line on the one surface of the substrate,

the n pieces of signal transmission lines are located on the one surface of the substrate along the arrangement direction of the plurality of light emitting elements,

the bonding pads are arranged at intervals therebetween along the arrangement direction of the plurality of light emitting elements,

the bonding pads comprises:
a first bonding pad connected to the first electrode;
second bonding pads connected to the respective second electrodes; and
third bonding pads connected to the third electrodes of the light emitting elements in respective ones of the plurality of light emitting element blocks, and a number of the third bonding pads being smaller than that of the plurality of light emitting elements, and

the n pieces of switching elements are located between the adjacent bonding pads.

According to the light emitting element array of the invention, the light emitting elements constituting the light emitting element array are arranged in a substantially straight line on one surface (hereinafter, this face is referred to as a “main face”) of a substrate, the n pieces of signal transmission lines are arranged in the arrangement direction of the light emitting elements, the bonding pads for supplying the first signal, the second signal, and the third signal are arranged at intervals therebetween along the arrangement direction of the light emitting elements, and the switching elements are located between the adjacent bonding pads.

Here, the number of necessary first bonding pads that are connected to the first electrodes and that are used for supplying the first signal is at least one because the first electrodes of the respective switching elements are electrically connected to each other. The number of necessary second bonding pads that are connected to the second electrodes and that are used for supplying the second signal is n pieces, which is equal to the number of switching elements, because the second signal has to be individually applied to each switching element constituting the light emitting element array. Furthermore, the number of necessary third bonding pads that are connected to the third electrodes and that are used for supplying the third signal is at least one for each light emitting element block because the third electrodes of the light emitting elements constituting each light emitting element block are electrically connected to each other, and it is sufficient that the total number of third bonding pads in the entire light emitting element array is smaller than the number of light emitting elements.

Accordingly, when the number of light emitting element blocks is m and the respective light emitting element blocks include n pieces of light emitting elements, the number of light emitting elements is min and the number of bonding pads at least required for supplying the first to third signals array is m+n+1 pieces. Accordingly, when a light emitting element array including a large number of light emitting elements is configured, the number of bonding pads is smaller than the number of light emitting elements and thus spaces are formed between the bonding pads. Therefore, the spaces can be effectively used to arrange the switching elements, and the increase in size of the entire light emitting element array due to disposition of the switching elements can be avoided, thereby embodying a small-sized light emitting element array.

Furthermore, in the light emitting element array of the invention, it, is preferable that the second electrodes are respectively connected to third resistors, and the second signal is applied to the second electrodes via the third resistors.

According to the light emitting element array of the invention, in the configuration of the light emitting element array including the light emission thyristors, the second signal is inputted to the anodes of the switch thyristors via the third resistors.

When the light emitting element arrays are used to configure a light emitting device, the first signal may be supplied to the plurality of light emitting element arrays at the same time for the purpose of high speed operation to concurrently select the plurality of light emitting element arrays. At this time, since the plurality of light emitting element arrays in the selected state share the second signal, the plurality of switch thyristors are switched at the same time. In general, when a light emission thyristor is switched to an on-state, main current flows between the anode and the cathode thereof and thus the output voltage of the driving circuit to supply the second signal is lowered. Accordingly, when the input timing of the second signal to the anodes of the plurality of switch thyristors is different, the switch thyristor to which the second signal is first inputted is switched and the main current flows therein. Then, the switch thyristors to which the second signal is lately inputted may not be switched due to the lack of the voltage of the second signal. Therefore, according to the above-mentioned configuration, by supplying the second signal through the third resistor connected to the anodes of the switch thyristors, it is possible to suppress the decrease in output voltage of the driving circuit and to satisfactorily switch the switch thyristors.

Further, in the light emitting element array of the invention, it is preferable that the light emission thyristors of the n pieces of switching elements and the plurality of light emitting elements comprise the same layer structure.

According to the light emitting element array of the invention, the semiconductor layers constituting the switch thyristor and the light emitting thyristor have the same layer configuration. In this case, the semiconductor layers forming the switch thyristor and the light emitting thyristor can be simultaneously formed in the same film-forming step, and thus, even in the configuration of the invention in which switching elements are arranged in addition to the light emitting element array, the manufacturing step is not complicated.

Furthermore, in the light emitting element array of the invention it is preferable that the light emitting element array comprises a light-blocking portion or a light-reducing portion for blocking or reducing light emitted from the light emission thyristor of the switching element.

According to the invention, a light-blocking portion or a light-reducing portion for blocking or reducing light emitted from the switch thyristor is included. The light-blocking portion or the light-reducing portion has the function of preventing light emitted when the switch thyristor is switched from entering the light emitting thyristor, and thus, the threshold voltage of the light emitting thyristor can be prevented from being changed by that light. Accordingly, in the case where the light emission thyristor forms the light emitting element and the switching element, the light emitting element array can be stably operated.

Furthermore, the invention is directed to a light emitting device, comprising:

the plurality of light emitting element arrays mentioned above;

a first driving circuit that is electrically connected to the first electrodes and that supplies the first signal;

a second driving circuit that is electrically connected to the second electrodes and that supplies the second signal; and

a third driving circuit that is electrically connected to the third signals and that supplies the third signal.

According to the light emitting device of the invention, a light emitting device including the plurality of light emitting element arrays, a first driving circuit that supplies the first signal to each of the light emitting element arrays, a second driving circuit that supplies the second signal, and a third driving circuit that supplies the third signal is provided. When the light emitting element arrays of the invention are used, a configuration is possible in which some of the plurality of light emitting element arrays are turned to a selected state according to the first signal supplied from the first driving circuit, and the light emitting element arrays not in a selected state do not emit light even when the second signal and the third signal are inputted. Accordingly, the light emitting device can be stably operated through time-division driving operation in which the second driving circuit and the third driving circuit are shared by the plurality of light emitting element arrays. Accordingly, the number of driving circuits and the number of substrate layers on which the driving circuits are mounted can be reduced, and the area of the light emitting element arrays and the driving circuit mounting substrate can be reduced. As a result, a small light emitting device that is stably operated can be realized.

Furthermore, the invention is directed to a light emitting device, comprising:

a light emitting element array portion comprising a plurality of light emitting element arrays, each comprising,
(a) n pieces of switching elements (n is an integer of 2 or more) each comprising a first electrode, a second electrode, and a first control electrode that outputs a control signal when a first signal is inputted into the first electrode and a second signal is inputted into the second electrode,
(b) n pieces of signal transmission lines respectively connected to the first control electrodes, and
(c) a plurality of light emitting elements that each comprises a third electrode, and a second control electrode connected to any one of the n pieces of signal transmission lines, and each emits light when a third signal is inputted into the third electrode and the control signal is inputted into the second control electrode, wherein
each of the n pieces of signal transmission lines is connected to the second control electrode of at least one of the light emitting elements,
the first electrodes of the n pieces of switching elements are electrically connected to each other,
the n pieces of switching elements and the plurality of light emitting elements each comprises a light emission thyristor having either one of a cathode and an anode thereof as a common electrode, and the n pieces of switching elements each further comprises a resistor,
(i) when the cathode is the common electrode,
   an N gate electrode of the light emission thyristor of each of the n pieces of switching elements is connected to one end of the resistor,
   the first electrode is connected to another end of the resistor,
   the second electrode is the anode of the light emission thyristor of each of the n pieces of switching elements,
   the third electrode is the anode of the light emission thyristor of each of the plurality of light emitting elements,
   the first control electrode is the N gate electrode of the light emission thyristor of each of the n pieces of the switching elements, and
   the second control electrode is an N gate electrode of the light emission thyristor of each of the plurality of light emitting elements, and
(ii) when the anode is the common electrode,
   a P gate electrode of the light emission thyristor of each of the n pieces of switching elements is connected to one end of the resistor,
   the first electrode is connected to another end of the resistor,
   the second electrode is the cathode of the light emission thyristor of each of the n pieces of switching elements,
   the third electrode is the cathode of the light emission thyristor of each of the plurality of light emitting elements,
   the first control electrode is the P gate electrode of the light emission thyristor of each of the n pieces of switching elements, and
   the second control electrode is a P gate electrode of the light emission thyristor of each of the plurality of light emitting elements;

a first driving circuit that is electrically connected to the first electrodes and that supplies the first signal;

a second driving circuit that is electrically connected to the second electrodes and that supplies the second signal; and

a third driving circuit that is electrically connected to the third signals and that supplies the third signal;

wherein the first driving circuit comprises a first signal level-setting portion that sets a potential at a high level and at a low level of the first signal having a high level and a low level.

According to the light emitting device of the invention, the light emitting element array includes n pieces of switching elements (n is an integer of 2 or more) that output a control signal when both of a first signal and a second signal axe inputted, n pieces of signal transmission lines through which the control signal is transmitted, and a plurality of (n or more) light emitting elements that emit light when the control signal from the signal transmission lines and a third signal are inputted. The first electrodes of the respective switching elements are electrically connected to each other between the switching elements, and, thus, a common first signal can be applied to all of the switching elements included in the light emitting element array.

In the case where a common first signal is inputted into each switching element constituting the light emitting element array, the control signal is outputted to the signal transmission line connected to the switching element into which the second signal is inputted. Furthermore, when the third signal is inputted into the light emitting element connected to the signal transmission line to which the control signal is outputted, that light emitting element emits light. On the other hand, in the case where a common first signal is not inputted into the light emitting element array, each switching element does not output the control signal even when the second signal is inputted, and thus, the light emitting element into which the third signal is inputted does not emit light even when the third signal is inputted into the light emitting element.

The light emitting device includes the plurality of light emitting element arrays, a first driving circuit that supplies the first signal to each of the light emitting element arrays, a second driving circuit that supplies the second signal, and a third driving circuit that supplies the third signal. Accordingly, in the light emitting device of the invention including the plurality of light emitting element arrays, a light emitting element belonging to which light emitting element array is to be caused to emit light can be selected according to the first signal (hereinafter, the light emitting element array into which the first signal is inputted is referred to as being “in a selected state”), and a configuration is possible in which some of the plurality of light emitting element arrays are turned to a selected state, and the light emitting element arrays not in a selected state do not emit light even when the second signal and the third signal are inputted. When the first signal is sequentially applied to each light emitting element array constituting the light emitting device so as to turn the light emitting element array to a selected state, the light emitting device can be stably operated through time-division driving operation in which wires between the light emitting element arrays and the second and the third driving circuits for applying the second signal and the third signal are shared by the plurality of light emitting element arrays. Accordingly, the number of driving circuits and the number of substrate layers on which the driving circuits are mounted can be reduced, and the area of the light emitting element arrays and the driving circuit mounting substrate can be reduced. As a result, a small light emitting device that is stably operated can be realized.

The signal level of the first signal is set by the first signal level-setting portion located outside the light emitting element array, and thus, the circuit of the light emitting element array can be simplified, and the chip size of the light emitting element array can be reduced. Furthermore, it is sufficient that one first signal level-setting portion is located in the first driving circuit shared by the plurality of light emitting element arrays, and thus, the configuration can be simplified without lowering the overall functionality of the light emitting device compared with the case in which a similar function is provided in each light emitting element array.

The switching element includes a light emission thyristor and a resistor, and the light emitting element includes a light emission thyristor. Here, the light emission thyristor constituting the switching element and the light emitting element is used such that a cathode or an anode is a common electrode (the potential Vg=0 V).

When the cathode is used as the common electrode, the N-gate electrode of the light emission thyristor in the switching elements and one end of the first resistor are connected. In this case, another end of the resistor corresponds to the first electrode to which the first signal is inputted, the anode of the light emission thyristor corresponds to the second electrode to which the second signal is inputted, and the N-gate electrode of the light emission thyristor corresponds to the first control electrode to which the control signal is outputted. Further, the light emitting element is formed of a light emission thyristor, the third electrode to which the third signal is inputted corresponds to the anode of the light emission thyristor, and the control electrode to which the control signal is inputted corresponds to the N-gate electrode of the light emission thyristor.

Hereinafter, an example of the circuit operation according to the above-described circuit configuration will be shown.

As the first signal, a signal at a low level (in which the potential is 2.5 V) or at a high level (in which the potential is 5 V) is applied to another end of the resistor. The first signal in which a potential at a low level and at a high level suitable for switching the switch thyristor is set in advance by the first signal level-setting portion of the first driving circuit is inputted into the N gate electrode of the light emission thyristor constituting the switching element (hereinafter, referred to as a “switch thyristor”). The first signal level-setting portion includes, for example, a plurality of resistors connected in series, and the a potential at the high level or at the low level of the first signal is set according to the voltage outputted from the connecting portion positioned at a point in the plurality of resistors connected in series. The potentials are controlled according to the divided voltage ratio of the plurality of resistors.

Furthermore, a signal at a high level is applied as the second signal to the anode of the switch thyristor, and, in a state where the second signal is not inputted, a voltage at a low level (in which the potential is 0 V) is set to be applied to the anode of the switch thyristor. The high level of the second signal is selected to be a value with which, in a state where Vd volts are applied to the N gate of the switch thyristor, when the second signal is inputted, the switch thyristor shifts from an off-state to an on-state. Accordingly, in a state where the first signal is inputted and Vd volts are applied to the N gate of the switch thyristor, when a second signal at a high level is inputted, the switch thyristor shifts to an on-state. When the switch thyristor shifts to an on-state, the N gate electrode of the switch thyristor corresponding to the first control electrode shifts from Vd to approximately 0 V, and approximately 0 V is outputted as the control signal. Furthermore, when the second signal is not inputted and a voltage at a low level is applied to the anode of the switch thyristor, the switch thyristor is kept in an off-state regardless of whether or not the first signal is inputted. That is to say, the switch thyristor functions as an AND circuit that shifts to an on-state and outputs a control signal only when the first and the second signals are inputted.

Furthermore, in the light emission thyristor constituting the light emitting element (hereinafter, referred to as a “light emitting thyristor”), the current and voltage characteristics, such as a threshold voltage, are the same as those of the switch thyristor. Furthermore, a signal at a high level is applied as the third signal to the anode of the light emitting thyristor, and, in a state where the third signal is not inputted, a voltage at a low level (in which the potential is 0 V) is set to be applied to the anode of the light emitting thyristor. The high level of the third signal is selected to be a value with which, in a state where Vd or vcc is applied to the N gate electrode of the light emitting thyristor, even when the third signal is inputted, the light emitting thyristor is kept in an off-state, and, in a state where a control signal of approximately 0 V is applied to the N gate electrode of the light emitting thyristor, when the third signal is inputted, the light emitting thyristor shifts to an on-state. Accordingly, in a state where the first and the second signals are inputted and the control signal is inputted into the N gate electrode of the light emitting thyristor, when the third signal is inputted, the light emitting thyristor shifts from an off-state to an on-state and emits light. Furthermore, in a state where at least one of the first and the second signals is not inputted and the control signal is not inputted, the light emitting thyristor is kept in an off-state regardless of whether or not the third signal is inputted. That is to say, the light emitting thyristor emits light only when all of the first, the second, and the third signals are inputted.

Accordingly, according to the invention, a logic circuit allowing the light emitting elements to selectively emit light by supplying the first to third signals can be configured with a sample circuit configuration using the light emission thyristors without using complex semiconductor devices such as NAND gates or inverters, thereby embodying a light emitting device with easy design and simple manufacturing processes.

Here, when the anode of the light emission thyristor is used as a common electrode, the above-described logic circuit can be realized in a similar manner by reversing the polarity of the light emission thyristor, and reversing the conductivity type of the gate electrode of the light emission thyristor.

Furthermore, in the invention, it is preferable that plurality of light emitting elements comprises a plurality of light emitting element blocks comprising n or less pieces of light emitting elements in which the third electrodes thereof are electrically connected to each other, and

the second control electrodes of the light emitting elements in one of the plurality of light emitting element blocks are connected to respective one of the n pieces of signal transmission lines which axe different with each other.

According to the light emitting device of the invention, the plurality of light emitting elements form light emitting element blocks including n or less pieces of light emitting elements, and, in the same light emitting element block, the third electrodes to which the third signal is applied are electrically connected to each other, and thus, a common third signal is applied to the light emitting elements belonging to the same light emitting element block. Furthermore, in the same light emitting element block, the light emitting elements are respectively connected to different signal transmission lines, and thus, different control signals are respectively applied. Accordingly, in a state where the light emitting element array is in a selected state due to the first signal, when the second signal is sequentially applied on a time-division basis to the switching elements of that light emitting element array, the control signal is sequentially transmitted also to the signal transmission lines connected to the switching elements, and the control signal is sequentially applied also to the light emitting elements in the same light emitting element block. Thus, when a common third signal is applied to each of the light emitting element blocks according to that timing, time-division driving operation in the light emitting element block can be realized. In this manner, in the invention, the plurality of light emitting element blocks in the same light emitting element array can perform time-division driving operation, and thus, the number of driving IC output terminals that supply the second signal and the third signals, and the number of wires between the driving ICs and the light emitting element arrays can be reduced, and a small light emitting device in which the number of wires is small can be realized. Furthermore, the number of signal transmission lines in the light emitting element array can be also reduced, and thus, a small light emitting device can be realized.

Furthermore, in the invention, it is preferable that the plurality of light emitting elements are arranged in a line,

each of the plurality of light emitting element blocks is composed of n−1 pieces of light emitting elements (n is an integer of 4 or more),

odd-numbered light emitting element blocks of the plurality of light emitting element blocks, which are numbered according to an order of from one end to the other end in an arrangement direction of the plurality of light emitting elements, each comprises an iᵢ-th light emitting element which is numbered according to the order of from one end to the other end in the arrangement direction, and the i₁-th light emitting is connected to a j₁-th signal transmission line so as to satisfy iᵢ=jᵢ (wherein i_{z} is an integer of 1 or more and n−1 or less and j₁ is an integer of 1 or more and n−1 or less), and

even-numbered light emitting element blocks of the light emitting element blocks, which are numbered according to an order of from one end to the other end in the arrangement direction of the plurality of light emitting elements, each comprises an i₂-th light emitting element which is numbered according to the order of from one end to the other end in the arrangement direction, and the iₓ-th light emitting is connected to a j₂-th signal transmission line so as to satisfy i₂+j₂=n+1 (wherein i₂ is an integer of 1 or more and n−1 or less and j₂ is an integer of 2 or more and n or less).

In the light emitting device of the invention, the respective light emitting element blocks include n−1 light emitting elements smaller by 1 than the number of signal transmission lines (n is an integer of 4 or more). Here, in a direction (referred to as an X₁ direction) from one end in the arrangement direction of the light emitting elements to the other end thereof, the light emitting elements of the respective light emitting element blocks are numbered with first to (n−1)-th numbers in the X₁ direction and the n pieces of signal transmission lines are numbered with first to n-th numbers in a predetermined order. According to the configuration, in the odd-numbered light emitting element blocks, the i₁-th light emitting element is connected to the j₁-th signal transmission line so as to satisfy i₁=j₁ (wherein and 1≦j₁≦n−1). In the even-numbered light emitting element blocks, the i₂-th light emitting element is connected to the j₂-th signal transmission line so as to satisfy i₂+j₂=n+1 (wherein 1≦i₂≦n−1 and 2≦j₂≦n).

In this case, the light emitting element adjacent to the light emitting element connected to the first signal transmission line in the arrangement direction is connected to the second signal transmission line. The light emitting element adjacent to the light emitting element connected to the j₃-th signal transmission line in the arrangement direction (wherein 2≦j₃≦n−1) is connected to one of the (j₃−1)-th and (j₃+1)-th signal transmission lines. The light emitting element adjacent to the light emitting element connected to the n-th signal transmission line in the arrangement direction is connected to the (n−1)-th signal transmission line. Accordingly, when the second signal is sequentially inputted to the switching elements in the light emitting element array selected by inputting the first signal and the control signal is time-divisionally sequentially outputted to the first to n-th signal transmission lines, the temporal difference in light emission timing between the adjacent light emitting elements can be reduced. Since the adjacent light emitting elements are not connected to the same signal transmission line, it is possible to prevent the adjacent light emitting elements from concurrently emitting light.

Accordingly, when the light emitting device configured to include the light emitting element array of the invention is used as an exposure device exposing a photoreceptor drum, the great difference in timing when the adjacent light emitting elements emit light is suppressed, whereby a discontinuous point is not generated at the exposure positions on the photoreceptor drum. Since the concurrent light emission of the adjacent light emitting elements is prevented, the difference in light emission of heat is suppressed when the light emitting elements emit light, thereby making constant the light emission characteristic with the variation in temperature of the light emitting elements. Since the interference of light emitted from the adjacent light emitting elements can be prevented, it is possible to expose the photoreceptor drum with high precision. As a result, in the image forming apparatus employing the light emitting element array of the invention, it is possible to obtain a recorded image with high image quality.

Furthermore, in the light emitting device of the invention, the light emitting device further comprises a substrate and bonding pads located on one surface of the substrate, wherein

the plurality of light emitting elements are arranged substantially in a straight line on the one surface of the substrate,

the n piece of signal transmission lines are located on the one surface of the substrate along the arrangement direction of the plurality of light emitting elements,

the bonding pads are arranged at intervals therebetween along the arrangement direction of the plurality of light emitting elements,

the bonding pads comprises:
a first bonding pad connected to the first electrode;
second bonding pads connected to the respective second electrodes; and
third bonding pads connected to the third electrodes of the light emitting elements in respective ones of the plurality of light emitting element blocks and located in the light emitting element blocks, and a number of the third bonding pads being smaller than that of the plurality of light emitting elements, and

the n pieces of switching elements are located between the adjacent bonding pads.

According to the light emitting device of the invention, the light emitting elements constituting the light emitting element array are arranged in a substantially straight line on one surface (hereinafter, this face is referred to as a “main face”) of a substrate, the n pieces of signal transmission lines are arranged in the arrangement direction of the light emitting elements, the bonding pads for supplying the first signal, the second signal, and the third signal are arranged at intervals therebetween along the arrangement direction of the light emitting elements, and the switching elements are located between the adjacent bonding pads.

Here, the number of necessary first bonding pads that are connected to the first electrodes and that are used for supplying the first signal is at least one because the first electrodes of the respective switching elements are electrically connected to each other. The number of necessary second bonding pads that are connected to the second electrodes and that are used for supplying the second signal is n pieces, which is equal to the number of switching elements, because the second signal has to be individually applied to each switching element constituting the light emitting element array. Furthermore, the number of necessary third bonding pads that are connected to the third electrodes and that are used for supplying the third signal is at least one for each light emitting element block because the third electrodes of the light emitting elements constituting each light emitting element block are electrically connected to each other, and it is sufficient that the total number of third bonding pads in the entire light emitting element array is smaller than the number of light emitting elements.

Accordingly, when the number of light emitting element blocks is m pieces and the respective light emitting element blocks includes n pieces of light emitting elements, the number of light emitting elements is m×n pieces and the number of bonding pads at least required for supplying the first to the third signals to is m+n+1 pieces. Accordingly, when a light emitting element array including a large number of light emitting elements is configured, the number of bonding pads is smaller than the number of light emitting elements and thus spaces are formed between the bonding pads. Therefore, the spaces can be effectively used to arrange the switching elements, and the increase in size of the entire light emitting element array due to disposition of the switching elements can be avoided prevented from being increased when the switching elements are arranged, thereby embodying a small-sized light emitting device.

Furthermore, in the light emitting device of the invention, it is preferable that the second resistors are respectively connected to the second electrodes, and the second signal is applied to the second electrodes via the second resistors.

According to the light emitting device of the invention, in the configuration of the light emitting element array including the light emission thyristors, the second signal is inputted to the anodes of the switch thyristors via the second resistors.

When the light emitting element arrays are used to configure a light emitting device, the first signal may be supplied to the plurality of light emitting element arrays at the same time for the purpose of high speed operation to concurrently select the plurality of light emitting element arrays. At this time, since the plurality of light emitting element arrays in the selected state share the second signal, the plurality of switch thyristors are switched at the same time. In general, when a light emission thyristor is switched to an on-state, main current flows between the anode and the cathode thereof and thus the output voltage of the driving circuit to supply the second signal is lowered. Accordingly, when the input timing of the second signal to the anodes of the plurality of switch thyristors is different, the switch thyristor to which the second signal is first inputted is switched and the main current flows therein. Then, the switch thyristors to which the second signal is lately inputted may not be switched due to the lack of the voltage of the second signal. Therefore, according to the invention, by supplying the second signal through the second resistor connected to the anodes of the switch thyristors, it is possible to suppress the decrease in output voltage of the driving circuit and to satisfactorily switch the plurality of switch thyristors.

Further, in the light emitting device of the invention, it is preferable that the light emission thyristors of the n pieces of switching elements and the plurality of light emitting elements comprise the same layer structure.

According to the light emitting device of the invention, the semiconductor layers forming the switch thyristor and the light emitting thyristor have the same layer configuration. In this case, the semiconductor layers forming the switch thyristor and the light emitting thyristor can be simultaneously formed in the same film-forming step, and thus, even in the configuration of the invention in which switching elements are arranged in addition to the light emitting element array, the manufacturing step is not complicated.

Furthermore, in the light emitting device of the invention, it is preferable that the light emitting device includes a light-blocking portion or a light-reducing portion for blocking or reducing light emitted from the light emission thyristor of the switching element.

According to the light emitting device of the invention, a light-blocking portion or a light-reducing portion for blocking or reducing light emitted from the switch thyristor is included. The light-blocking portion or the light-reducing portion has the function of preventing light emitted when the switch thyristor is switched from entering the light emitting thyristor, and thus, the threshold voltage of the light emitting thyristor can be prevented from being changed by that light. Accordingly, in the case where the light emission thyristor forms the light emitting element and the switching element, the light emitting element array can be stably operated.

Furthermore, in the light emitting device of the invention, it is preferable that the first signal level-setting portion comprises a plurality of resistors that are connected in series and that output a voltage for setting the potentials from a connecting portion connecting the plurality of resistors with each other.

Furthermore, an image forming apparatus of the invention comprises:

any of the light emitting devices of the invention mentioned above;

a light condensing portion configured for condensing light from the n pieces of light emitting elements of the light emitting device on a photoreceptor drum;

a developer supplying portion configured for supplying a developer to the photoreceptor drum on which the light from the light emitting device is condensed by the light condensing portion so that the photoreceptor is exposed to the light;

a transfer portion configured for transferring an image formed on the photoreceptor drum by the developer onto a recording sheet; and

a fixing portion configured for fixing the developer transferred onto the recording sheet,

wherein the first, second and third driving circuits, and the third driving circuit supply the first, second and third signals, and the third signals, respectively, based on image information.

According to the image forming apparatus of the invention, an image forming apparatus using the light emitting device is provided. In the image forming procedure, first, the light emitting device is driven by the use of the first signal driving circuit, the second signal driving circuit, and the light emission signal driving circuit on the basis of the image information and the light from the light emitting device is condensed on the charged photoreceptor drum by the light condensing portion, whereby the photoreceptor drum is exposed to the light and an electrostatic latent image is formed on the surface thereof. Then, when the developer is supplied to the photoreceptor drum having the electrostatic latent image formed thereon by the developer supplying portion, the developer is attached to the photoreceptor drum to form an image. Finally, the image formed on the photoreceptor drum by the developer is transferred onto the recording sheet by the transfer portion and the developer transferred onto the recording sheet is fixed by the fixing portion, whereby an image is formed on the recording sheet. Since the light emitting device has a small size and has high reliability for stable operation, it is possible to obtain an image forming apparatus that can stably form an image with excellent image quality.

### BRIEF DESCRIPTION OF DRAWINGS

Other and further objects, features, and advantages of the invention will be more explicit from the following detailed description taken with reference to the drawings.

FIG. 1 is a schematic equivalent circuit diagram showing a light emitting element array chip 1 as a light emitting element array according to a first embodiment of the invention;

FIG. 2 is a graph illustrating a forward voltage-current characteristic which is a relation between the anode voltage and the anode current of the light emitting thyristor T;

FIG. 3 is a diagram extracting part of the equivalent circuit diagram shown in FIG. 1 in order to illustrate an operation of a light emitting element array chip L1;

FIG. 4 is a logic circuit chart in which the equivalent circuit diagram shown in FIG. 3 is indicated by logic circuit chart symbols;

FIG. 5 is a graph illustrating an example of an operating characteristic of the light emitting element array chip 1 according to the first embodiment;

FIG. 6 is a partial plan view illustrating a basic configuration of the light emitting element array chip 1 according to the first embodiment;

FIG. 7 is a partial sectional view illustrating a basic configuration of the light emitting element array chip 1 as viewed from line VII-VII of FIG. 6;

FIG. 8 is a partial sectional view illustrating a basic configuration of the light emitting element array chip 1 as viewed from line VIII-VIII of FIG. 6;

FIG. 9 is a partial sectional view illustrating a basic configuration of the light emitting element array chip 1 as viewed from section line IX-IX of FIG. 6:

FIG. 10 is a block diagram schematically illustrating a light emitting device 10 according to an embodiment of the invention;

FIG. 11 is a timing chart showing the operation of a light emitting device 10;

FIG. 12 is a side view illustrating a basic configuration of an image forming apparatus employing the light emitting element array chip 1;

FIG. 13 is a schematic equivalent circuit diagram showing a light emitting element array chip 4 according to a second embodiment of the invention;

FIG. 14 is a block circuit diagram schematically showing a light emitting device 210 according to another embodiment of the invention;

FIG. 15 is a schematic equivalent circuit diagram showing the light emitting element array chip 201 included in the light emitting device 210;

FIG. 16 is a diagram showing an example of the configuration of part of the selection signal driving IC 232;

FIG. 17 shows a circuit diagram for simulating the operational characteristics of the light emitting element array chip 201; and

FIG. 18 is a graph showing an example of the operational characteristics of the circuit in FIG. 17.

### BEST MODE FOR CARRYING OUT THE INVENTION

Now referring to the drawings, preferred embodiments of the invention are described below.

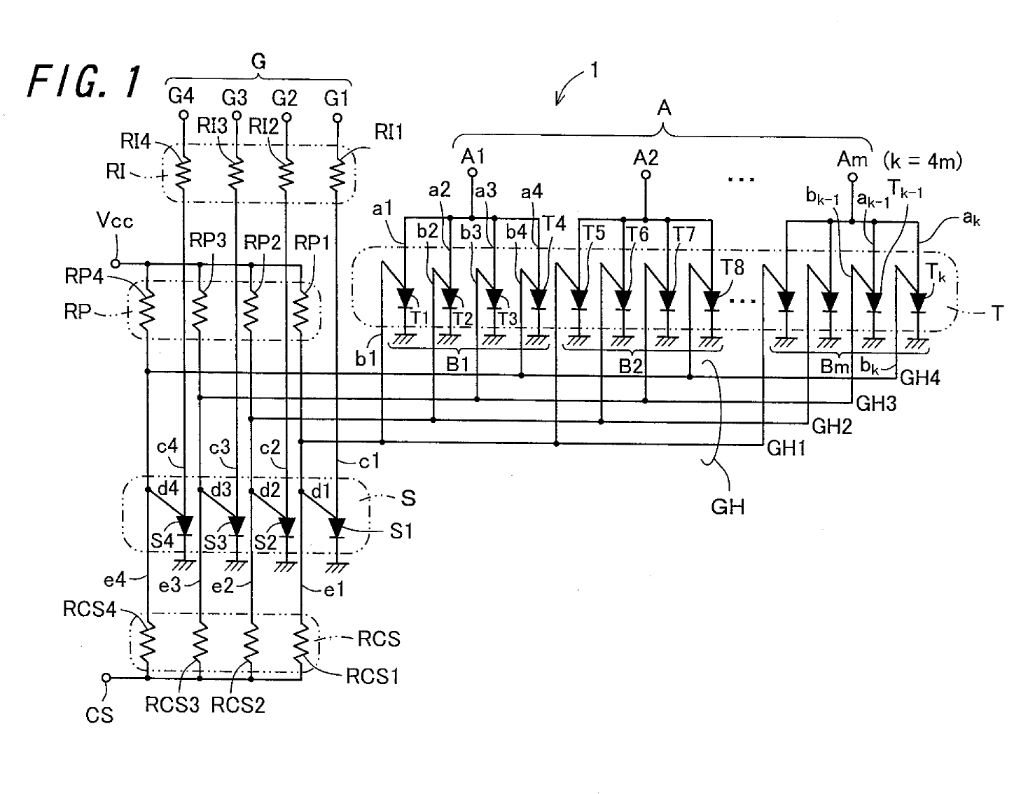

FIG. 1 is a schematic equivalent circuit diagram showing a light emitting element array chip 1 as a light emitting element array according to a first embodiment of the invention.

The light emitting element array chip 1 includes k pieces of light emitting elements (the symbol k is a natural number), n pieces of switching elements (n is an integer of 2 or more), and n pieces of horizontal gate lines GH1 to GHn. Each of the k pieces of light emitting elements includes a light emission thyristor. The n pieces of switching elements include switch thyristors S1 to Sn consisting of n light emission thyristors, n pieces of pull-up resistors RP1 to RPn corresponding to the first resistors, and n pieces of CS resistors RCS1 to RCSn corresponding to the second resistors. In this embodiment, a case will be described in which n=4. Hereinafter, the k pieces of light emitting elements may be respectively referred to as light emitting thyristors T1 to Tk. Furthermore, in the case where the plurality of light emitting thyristors T1 to Tk, the plurality of switch thyristors S1 to Sn, the plurality of CS resistors RCS1 to RCSn, and the plurality of pull-up resistors RP1 to RPn are collectively referred to, or in the case where each unspecified constituent element is referred to, that constituent element may be simply respectively referred to as a light emitting thyristor T, a switch thyristor S, a CS resistor RCS, and a pull-up resistor RP. In this embodiment, the horizontal gate lines GH correspond to the signal transmission lines.

Anodes a1 to alp and N-gate electrodes b1 to bk are used as electrodes to control operations of the light emitting thyristors T1 to Tk constituting the light emitting elements. The cathodes of the light emitting thyristors T are grounded as a common electrode. The anodes a1 to ak and the N-gate electrodes b1 to bk may be described as anodes a and N-gate electrodes b, when they are collectively referred to or when the unspecified ones are mentioned. The N-gate electrode b may be described simply as gate electrode b. In this embodiment, the anode a corresponds to the third electrode and the N-gate electrode b corresponds to the second control electrode.

Anodes c1 to c4 and N-gate electrodes d1 to d4 are used as electrodes to control operations of the switch thyristors S1 to S4 of the switching elements. The cathodes of the switch thyristors S are grounded as a common electrode. The anodes c1 to c4 and the N-gate electrodes d1 to d4 may be described as anodes c and N-gate electrodes d, when they are collectively referred to or when the unspecified ones are mentioned. The N-gate electrode d may be described simply as gate electrode d. In this embodiment, the anode c corresponds to the first electrode and the N-gate electrode d corresponds to the first control electrode.

The N gate electrodes d1 to d4 of the switch thyristors S1 to S4 are connected to one ends of the CS resistors RCS1 to RCS4, one ends of the pull-up resistors RP1 to RP4, and the horizontal gate lines GH1 to GH4. The elements that are connected to each other are denoted by the same reference numerals. For example, the N gate electrode d1 of the first switch thyristor S1 is connected to the first CS resistor RCS1, the first pull-up resistor RP1, and the first horizontal gate line GH1. An N gate electrode di₄ of an i₄-th switch thyristor Si₄ (1≦i₄≦n, wherein n=4) is connected to an i₄th CS resistor RCSi₄, pull-up resistor RPi₄, and horizontal gate line GHi₄. Furthermore, ends on the other side of the CS resistors RCS are connected to a selection signal input terminal CS, into which a common selection signal is inputted, and electrically connected to each other. Ends on the other side of the pull-up resistors RP are connected to a supply voltage input terminal Vcc, into which a common supply voltage is inputted. The horizontal gate line GH transmits the control signal outputted from the N gate electrode d of the switch thyristor S. In this embodiment, the anodes c1 to c4 of the switch thyristors S correspond to the second electrodes, and the selection signal corresponds to the first signal.

The anodes c1 to c4 of the switch thyristors S are connected to gate signal input terminals G1 to G4, respectively. Preferably, current-limiting resistors RI1 to RI4 are connected between the anodes c1 to c4 of the switch thyristors S and the gate signal imputer terminals G1 to G4. The gate signal input terminals G1 to G4 and the current-limiting resistors RI1 to RI4 may be simply described as gate signal input terminals G and current-limiting resistors RI, when they are collectively referred to or when the unspecified ones are mentioned. In this embodiment, the gate signal corresponds to a second signal and the current-limiting resistor RI corresponds to a third resistor connected to the anode or cathode of the switch thyristor.

The light emitting thyristors T used as the light emitting elements are composed of m light emitting element blocks B1 to Bm, each of which is composed of a group of n or less pieces of light emitting thyristors T. The plurality of light emitting element blocks B1 to Bm may be simply described as a light emitting element blocks B, when they are collectively referred to or when the unspecified ones are mentioned. The number of light emitting thyristors T of one light emitting element block B should be n or less. In this embodiment, n=4 and the number of light emitting thyristors T of all the light emitting element blocks is set to n (=4). Accordingly, the relation between the number k of light emitting thyristors T and the number m of light emitting element blocks B is k=4m. When the light emitting thyristors T are numbered with first to k-th numbers according to an order of from one end to the other end in the arrangement direction of the light emitting thyristors T and the light emitting element blocks are numbered with first to m-th numbers according to the order of from the one end to the other end in the arrangement direction, the (4i₅−3)-th to the 4i₅-th light emitting thyristors T belong to the i₅-th light emitting element blocks Bi₅ (wherein 1≦i₈≦m).

The light emitting element blocks B1 to Bm are provided with light emission signal input terminals A1 to Am, respectively. The light emission signal input terminals A1 to Am may be simply described as light emission signal input terminals A, when they are collectively referred to or when the unspecified ones are mentioned. The light emitting thyristors T of the light emitting element blocks B are electrically connected to each other by connecting the anodes a to a common light emission signal input terminal A of the light emitting element blocks B. The N-gate electrodes b of the light emitting thyristors T of the light emitting element blocks B are connected to different horizontal gate lines GH, respectively. When the horizontal gate lines are numbered with first to fourth numbers according to the wiring order, the gate electrode of the (4i₆−3)-th light emitting thyristor T4i₆−3 in the i₆-th light emitting element block Bi₆ (wherein 1≦i₆≦m) is connected to the first horizontal gate line GH1, the gate electrode of the (4i₆−2)-th light emitting thyristor is connected to the second horizontal gate line GH2, the gate electrode of the (4i₆−1)-th light emitting thyristor T4i₆−1 is connected to the third horizontal gate line GH3, and the gate electrode of the 4i₆-th light emitting thyristor T4i₆ is connected to the fourth horizontal gate line GH4. The anodes of all the light emitting thyristors T in the i₆-th light emitting element block Bi₆ (wherein 1≦i₆≦m) are connected to a common light emission signal input terminal Ai₆.

The configurations and operations of the light emitting thyristors T and the switch thyristors S used in the light emitting element array chip 1 will be described now.

In general, a light emission thyristor is a semiconductor element having a PNPN structure in which direct transition P-type semiconductor and N-type semiconductor are alternately stacked and has the same negative resistance characteristic as a reverse blocking triode thyristor. When is assumed that the semiconductor layers are sequentially a first semiconductor layer (N type), a second semiconductor layer (P type), a third semiconductor layer (N type, and a fourth semiconductor layer (P type) from the cathode side to the anode side, the N-gate electrode means a control electrode located in the third semiconductor layer (N type) and the P-gate electrode means a control electrode located in the second semiconductor layer (P type). The N-gate electrode is used to ground the cathode as a common electrode and the P-gate electrode is used to ground the anode as a common electrode. Depending on the anode or the cathode used as the common electrode, it is determined which conductive type of gate electrode should be used. Accordingly, when the common electrode is determined, it may be described simply as a gate electrode b. Here, the voltage of a light emission signal means a voltage to be applied across the anode and the cathode of the light emitting thyristor T with the application of the light emission signal to the anode a. The current of the light emission signal means a current to flow in the anode of the light emitting thyristor T with the application of the light emission signal. The voltage of a control signal means a voltage to be applied across the N-gate electrode b and the cathode of the light emitting thyristor T with the application of the control signal to the N-gate electrode b. The current of the control signal means a current to flow in the N-gate electrode b with the application of the control signal.

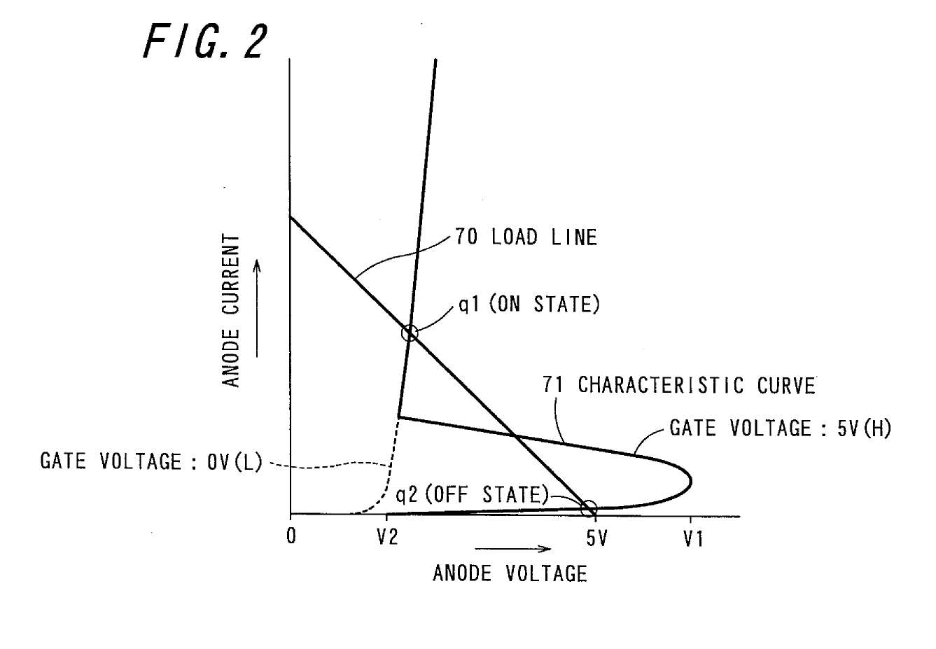

FIG. 2 is a graph illustrating a forward voltage-current characteristic which is a relation between the anode voltage and the anode current of the light emitting thyristor T. The anode voltage represents the potential of the anode when the potential of the cathode is 0 (zero) V and the anode current represents the current flowing in the anode.

In FIG. 2, the horizontal axis represents the anode voltage and the vertical axis represents the anode current. A load line 70 is also shown in FIG. 2. Since the threshold voltage of the light emitting thyristor T decreases with the application of the control signal to the gate electrode b, the operating point is changed from point q2 in an off-state where a characteristic curve 71 representing the forward voltage-current characteristic and the load line 70 intersect each other, to point q1 in an on-state where the characteristic curve 71 and the load line 70 intersect each other, thereby emitting light. At point q1 in an on-state, a main current flows between the anode and the cathode.

The operation of the light emitting thyristor T will be described now with specific numerical values. Here, the voltage of the cathode is 0 V and the potential of 5 V is applied to the anode a when the anode voltage is at a high (H) level, and the potential of 0 V is applied to the anode a when the anode voltage is at a low (L) level. The potential of 5 V is applied to the gate electrode b when the voltage of the gate electrode b is at the high (H) level, and the potential of 0 V is applied to the gate electrode b when the voltage of the gate electrode b is at the low (L) level.

First, when the voltage of the gate electrode b is at the high (H) level, the potential of the gate electrode b is 5 V. Accordingly, in order to allow the anode current to flow, a potential higher than the potential of 5 V of the gate electrode b by the forward voltage drop of a diode formed by the third semiconductor layer (N type) and the fourth semiconductor layer (P type) needs to be applied to the anode a. The forward voltage drop is about 1.5 V when the light emission thyristor is formed of GaAs or AlGaAs. Accordingly, when the light emission signal is at the high (H) level, the light emitting thyristor T is in an off-state of point q2 and thus does not emit light. When the voltage of the gate electrode b is at the low (L) level, the potential of the gate electrode b is 0 V. Accordingly, in order to allow the anode current to flow, a potential higher than the potential of 0 V of the gate electrode b by the forward voltage drop of a diode formed by the third semiconductor layer (N type) and the fourth semiconductor layer (P type) needs to be applied to the anode a. Accordingly, when the anode voltage is at the high (H) level, the light emitting thyristor T is in an on-state of point q1 and thus the anode current flows, thereby emitting light.

The configuration and the operations of the switch thyristor S are similar to those of the light emitting thyristor T.

Next, a schematic operation of the light emitting element array chip 1 shown in FIG. 1 will be described with reference to an equivalent circuit diagram.

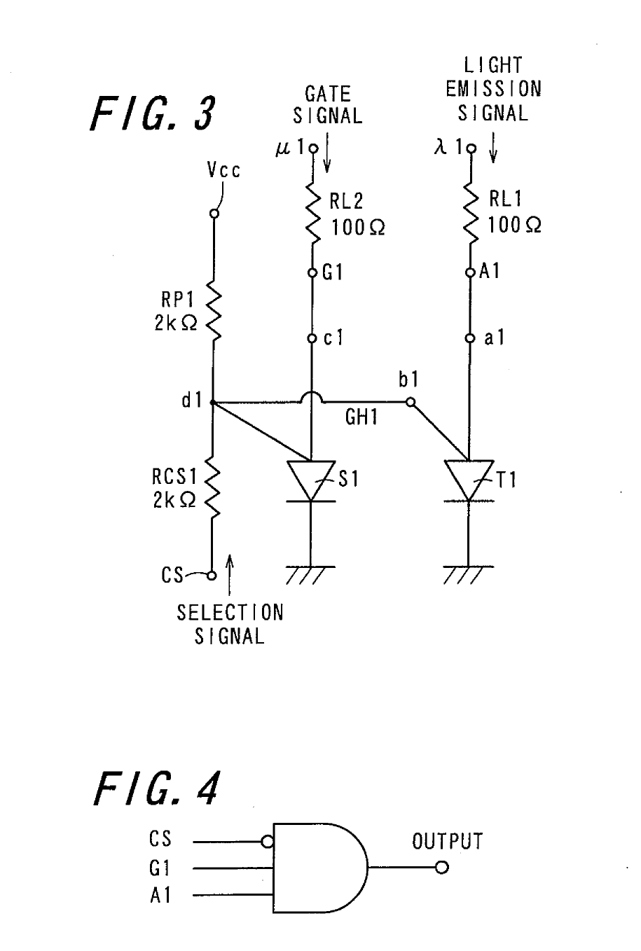

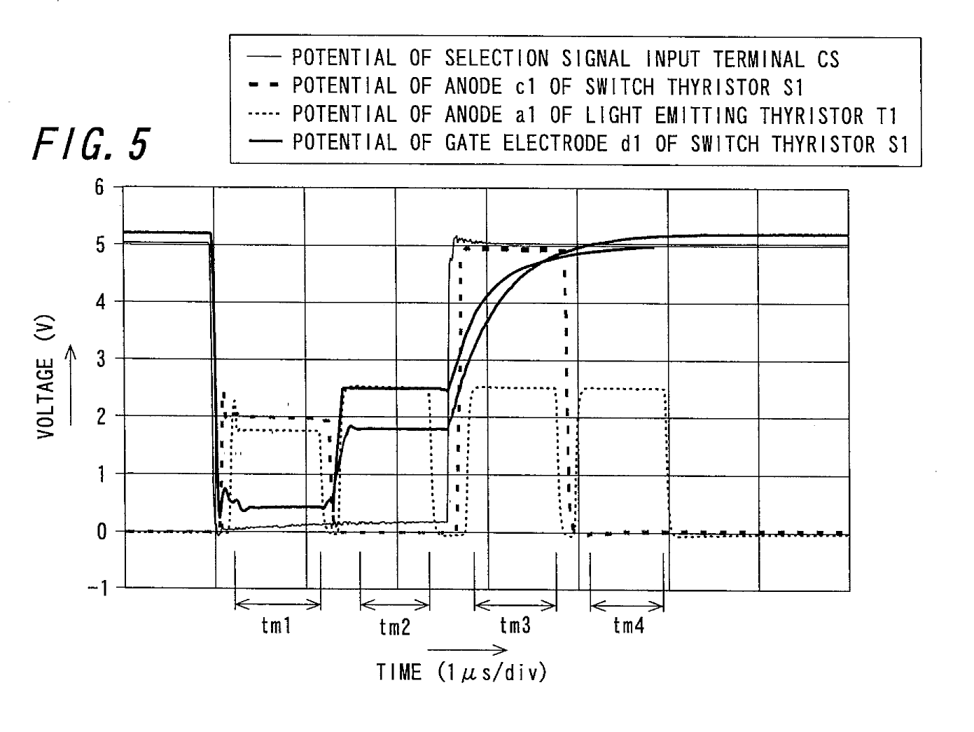

FIG. 3 is a diagram extracting part of the equivalent circuit diagram shown in FIG. 1 in order to illustrate en operation of a light emitting element array chip 1. FIG. 4 is a logic circuit chart in which the equivalent circuit diagram shown in FIG. 3 is indicated by logic circuit chart symbols. In FIG. 3, constituent elements corresponding to those of FIG. 1 are denoted by the same reference numerals, and a description thereof is omitted. Here, in FIG. 3, load resistors RL1 and RL2 of 100Ω are arranged between the light emission signal input terminal A1 and the light emission signal output terminal λ1, and between the gate signal input terminal G1 and the gate signal output terminal μ1. Furthermore, the size of the pull-up resistor RP1 is set to 2 kΩ, the size of the CS resistor RCS1 is set to 2 kΩ, and 5 V is inputted as a supply voltage Vcc to another end of the pull-up resistor RP1. Here, the current-limiting resistor RI shown in FIG. 1 is exemplified as a more preferable configuration, and, thus, is not used in FIGS. 3 and 5. A basic operation of the light emitting element array chip 1 is the same regardless of whether or not the current-limiting resistor RI is included.

FIG. 5 is a graph illustrating an example of an operating characteristic of the light emitting element array chip 1 according to this embodiment. Here, the horizontal axis represents the time (unit: micro second (μs)/div) and the vertical axis represents the signal level (unit: volt (V)). Regarding relations between FIGS. 3 and 5, in FIG. 5, a thick solid line represents the potential of the gate electrode d1 of the switch thyristor 8, a thin solid line represents the potential of the selection signal input terminal CS, a thick dashed line represents the potential of the anode of the switch thyristor S1, and a thin dashed line represents the potential of the anode a1 of the light emitting thyristor T1. The first light emitting thyristor T1, and the switch thyristor S1 shown in FIG. 3 are measured, but the same results can also be obtained from the other elements.

In the measurement of operational characteristics shown in FIG. 5, a current at a high (H) level of 5 mA is applied as the light emission signal, and, when the light emission signal is not applied, the state is set to a low (L) level and no current flows through the light emitting thyristor T (0 mA). Furthermore, a voltage at a high (H) level of 5 V is applied as the gate signal to the gate signal input terminal G, and, when the gate signal is not applied, the state is set to a low (L) level and a potential of 0 V is applied. Furthermore, a potential at a low (L) level of 0 V is applied as the selection signal to the selection signal input terminal CS, and, when the selection signal is not applied, the state is set to a high (H) level and a potential of 5 V is applied. Furthermore, in the measurement, 5 V is applied as the supply voltage Vcc to another end of the pull-up resistor RP1. The load resistors RL1 and RL2, the pull-up resistor PR1, and the CS resistor RCS1 are set to the same as those shown in FIG. 3, and the current-limiting resistor RI used as a preferable embodiment is not included.

First, in the time period tm1 shown in FIG. 5, the state is such that the gate signal, the selection signal, and the light emission signal are inputted, that is, the voltage of the gate signal input terminal G is set to a high level (5 V), the voltage of the selection signal input terminal CS is set to a low level (0 V), and the current that is caused to flow through the light emission signal input terminal is set to a high level (5 mA).

In this case, the selection signal input terminal CS is approximately 0 V as indicated by the thin solid line, and the supply voltage Vcc is 5 V. In the case where the switch thyristor S1 and the light emitting thyristor T1 are in an off-state, the potential of the gate electrode d1 is approximately 2.5 V, which is according to a divided voltage ratio of the CS resistor RCS1 and the pull-up resistor RP1, but, in the time period tm1, the switch thyristor S1 shifts to an on-state because a voltage at a high level (5 V) is applied to the anode c1 of the switch thyristor S1. As a result, the potential of the gate electrode d1 indicated by the thick solid line is approximately 0 V. In this state, the gate electrode d1 of the switch thyristor S1 and the gate electrode b1 of the light emitting thyristor T1 are connected to each other via the horizontal gate line GH1, and thus, the potential of the gate electrode b1 of the light emitting thyristor T1 is also approximately 0 V. This means that a control signal at a low level (0 V) is transmitted from the gate electrode d1 of the switch thyristor S1 via the horizontal gate line GH1 and inputted into the gate electrode b1 of the light emitting thyristor T1. Furthermore, since a light emission signal at a high level (5 mA) is applied also to the anode a1 of the light emitting thyristor T1, the light emitting thyristor T1 also shifts to an on-state and emits light. In the case where the light emitting thyristor T1 is in an on-state in this manner, the potential of the anode a1 of the light emitting thyristor T1 indicated by the thin dashed line is approximately 1.8 V, which is a drive voltage level of the light emitting thyristor T. Furthermore, the potential of the anode c1 of the switch thyristor S1 indicated by the thick dashed line is approximately 2 V, which is a drive voltage level of the switch thyristor S when the switch thyristor S1 is in an on-state.

Next, in the time period tm2 shown in FIG. 5, the state is such that the selection signal and the light emission signal are inputted and the gate signal is not inputted, that is, the voltage of the gate signal input terminal G is set to a low level (0 V), the voltage of the selection signal input terminal CS is set to a low level (0 V), and the current that is caused to flow through the light emission signal input terminal is set to a high level (5 mA).

Also in this case, the selection signal input terminal CS is approximately 0 V as indicated by the thin solid line. However, contrary to the time period tm1, the voltage of the gate, signal input terminal G is at a low level (0 V), and thus, the potential of the anode c1 of the switch thyristor S1 indicated by the thick dashed line is 0 V, and the switch thyristor S1 is in an off-state. Accordingly, the potential of the gate electrode d1 of the switch thyristor S1 indicated by the thick dashed line is approximately 2.5 V, which is according to a divided voltage ratio of the CS resistor RCS1 and the pull-up resistor RP1, and the potential of the gate electrode b1 of the light emitting thyristor T1 connected to the gate electrode d1 is also approximately 2.5 V. A light emission signal at a high level (5 mA) is applied to the anode a1 of the light emitting thyristor T1, but this signal is lower than the threshold voltage of the light emitting thyristor T1 in this case, and thus, the state is an off-state. Furthermore, the potential of the anode a1 of the light emitting thyristor T1 indicated by the thin dashed line is 2.5 V, which is a potential obtained when a current of 5 mA, that is at a light emission signal input level flows.

Next, in the time period tm3 shown in FIG. 5, the state is such that the gate signal and the light emission signal are inputted and the selection signal is not inputted, that is, the voltage of the gate signal input terminal G is set to a high level (5 V), the voltage of the selection signal input terminal CS is set to a high level (5 V), and the current that is caused to flow through the light emission signal input terminal is set to a high level (5 mA).

In this case, the selection signal input terminal CS is approximately 5 V as indicated by the thin solid line. The potential of the gate electrode d1 of the switch thyristor S1 indicated by the thick solid line is also approximately 5 V, but, in the experimental results shown in FIG. 5; the potential is 3 to 5 V in the time period tm3 according to a CR time constant. A voltage at a high level (5 V) is applied to the gate signal input terminal G, but, since the potential of the gate electrode d1 is high, the threshold voltage is higher than the voltage level of the gate signal, and the swatch thyristor in an off-state. Accordingly, the potential of the anode c1 of the switch thyristor S1 indicated by the thick dashed line is 5 V, which is a gate signal input level. In a similar manner, a light emission signal at a high level (5 mA) is applied to the light emitting thyristor T1, but the potential of the gate electrode b1 connected to the gate electrode d1 of the switch thyristor S1 is high, and thus, the light emitting thyristor T1 is in an off-state. Accordingly, the potential of the anode a1 of the light emitting thyristor T1 indicated by the thin dashed line is 2.5 V, which is a potential obtained when a current of 5 mA that is at a light emission signal input level flows.

Lastly, in the time period tm4 shown in FIG. 5, the state is such that only the light emission signal is inputted and the gate signal and the selection signal are not inputted, that is, the voltage of the gate signal input terminal G is set to a low level (0 V), the voltage of the selection signal input terminal CS is set to a high level (5 V), and the current that is caused to flow through the light emission signal input terminal is set to a high level (5 mA).

In this case, as indicated by the thin solid line, the selection signal input terminal CS is at about 5 V and the gate electrode d1 of the switch thyristor S1 indicated by the thick solid line is at about 5 V. In addition, since the voltage of the gate signal input terminal G is the low level (0 V), the potential of the anode c1 of the switch thyristor S1 indicated by the thick clashed line is 0 V, and thus, the switch thyristor S1 is in an off-state. On the other hand, the light emission signal of the high level (5 mA) is applied to the light emitting thyristor T1, but the potential of the gate electrode b1 connected to the gate electrode d1 of the switch thyristor S1 is 5 V which is higher, the light emitting thyristor T1 is in an off-state. Accordingly, the potential of the anode a1 of the light emitting thyristor T1 indicated by the thin dashed line is 2.5 V for 5 mA current of the input level of the light emission signal.

As described above, in the time period tm1, when the gate signal is applied to the anode c1 of the switch thyristor S1 in a state where the selection signal is applied, the switch thyristor S1 is turned to an on-state, and the potential of the gate electrode d1 is turned to a low level (0 V). The potential at a low level (0 V) of the gate electrode d1 is transmitted as the control signal via the horizontal gate line GH1 to the gate electrode d1 of the switch thyristor S1, and the potential of the gate electrode b1 of the light emitting thyristor T1 is also turned to 0 V. Then, when the light emission signal is applied to the anode a1 of the light emitting thyristor T1 in a state where the control signal is applied, the light emitting thyristor T1 can emit light. In this manner, only when all three signals consisting of the selection signal, the gate signal, and the light emission signal are applied, does the light emitting thyristor T1 emit light, and, when even only one of the three signals is not applied, the light emitting thyristor T1 does not emit light.

Truth values of the circuit shown in FIGS. 3 and 4 are listed in Table 1. In Table 1, the light emitting thyristor T1 emits light when the output is at the high (H) level, and the light emitting thyristor T1 is extinguished when the output is at the low (L) level. As can be seen from Table 1, only when the selection signal input terminal CS is at the low (L) level, the gate signal input terminal G1 is at the high (H) level, and the light emission signal input terminal A1 is at the high (H) level, the light emitting thyristor T1 can be selectively made to emit light.

TABLE 1

| CS | G1 | A1 | Output |
|---|---|---|---|
| H | H | H | L |
| H | H | L | L |
| H | L | H | L |
| H | L | L | L |
| L | H | H | H |
| L | H | L | L |
| L | L | H | L |
| L | L | L | L |

The same is true in the light emitting element array chip 1 shown in FIG. 1. The gate electrodes d of the switch thyristors S of the light emitting element array chip 1 are connected to the common signal input terminal CS. Accordingly, when the voltage of the low level is inputted from the common signal input terminal CS, the potential of all the gate electrodes d1 to d4 of the switch thyristors S1 to S4 becomes a potential determined by a voltage dividing ratio between a resistance value of the CS resistor-RCS and a resistance value of the pull-up resistor RP (e.g. in this embodiment, about 2.5 V when the voltage dividing ratio is 1:1). In this state, the light emitting element array chip 1 is selected (in a selected state). In the selected state, when the gate signal is inputted to the anode ci₇ of the i₇-th switch thyristor Si₇ from the i₇-th gate signal input terminal Gi₇ (wherein the i₇-th switch thyristor Si₇ is changed to an on-state. Then, the voltage of the gate electrode di₇ of the i₇-th switch thyristor Si₇ is about 0 V, and thus, the voltage of the i₇-th horizontal gate line GHi₇ connected to the gate electrode di₇ and the gate electrode b of the light emitting thyristor T connected to the i₇-th horizontal gate line is about 0 V. This means that the control signal of the low level (0 V) is inputted to the gate electrode b of the light emitting thyristor T through the horizontal gate line GHi₇ from the gate electrode di₇ of the switch thyristor Si₇. Further, by applying the light emission signal to the anode a of the light emitting thyristor T connected to the i₇-th horizontal gate line GHi₇, it is possible to allow the light emitting thyristor T to selectively emit light.

As described above, when the selection signal of the low level is inputted and the switch thyristors S are in the selected state, the switch thyristor S having the anode c to which the gate signal is inputted among the switch thyristors S is changed to an on-state. When the switch thyristor S is changed to an on-state, the potential of the gate electrode d is 0 V and the potential of the gate electrode b of the light emitting thyristor T connected to the switch thyristor S through the horizontal gate line is 0 V. When the light emission signal is inputted to the anode a of the light emitting thyristor T in this state, the light emitting thyristor is changed to an on-state to emit light. When the selection signal is not inputted when it is not in the selected state) and the gate signal is inputted to the anode c of the switch thyristor S of the light emitting element array chip 1, the switch thyristor S is not changed to an on-state. Accordingly, even when the light emission signal is applied to the anodes a of the light emitting thyristors T connected to the switch thyristor S through the horizontal gate line GH, the light emitting thyristors T are not made to emit light. In this way, since it can be controlled by the use of the selection signal whether the gate signal is supplied from the switch thyristors S to the light emitting thyristors T, the light emitting device employing the plurality of light emitting element array chips can be time-divisionally driven by sharing the light emission signal and the gate signal with the light emitting element array chips.

Further, in the light emitting element array chip 1 shown in FIG. 1, since the anodes a in the light emitting element blocks B are connected to the common light emission signal input terminal A, the light emitting element array chip 1 can be dynamically driven. In FIG. 1, the light emission signal is inputted to the light emission signal input terminal A located every light emitting element block B. While the light emission signal is applied to the anodes of all the light emitting thyristors T in the selected light emitting element block B, the light emitting thyristors T belonging to the block are connected to the different horizontal gate lines GH. Therefore, the light emitting thyristors T can be selectively made to emit light by the use of the gate signal.

Then, since the horizontal gate lines GH can be shared by the plurality of light emitting element blocks B, it is possible to time-divisionally drive the plurality of light emitting element blocks. Even when the number of light emitting thyristors T is great, it is possible to reduce the number of horizontal gate lines GH, thereby reducing the chip size. Since the number of horizontal gate lines GH is reduced, it is possible to simplify the configuration in which the number of switch thyristors S is small.

Furthermore, in the light emitting element array chip 1 shown in FIG. 1, as a preferable configuration, the current-limiting resistors RI1 to RI4 are connected between the anodes c1, c2, c3, and c4 of the switch thyristor S and the gate signal input terminals G1, G2, G3, and G4. Here, in the case where a plurality of current-limiting resistors are collectively referred to, or in the case where each unspecified constituent element is referred to, that constituent element may be simply referred to as a current-limiting resistor RI.

When the light emitting device is configured by employing the light emitting element arrays, for the purpose of high speed operation, the selection signal is concurrently applied to the plurality of light emitting element array chips 1 to concurrently make the plurality of light emitting element array chips 1 in the selected state. At this time, since the gate signal is shared by the plurality of light emitting element array chips 1 in the selected state, the plurality of switch thyristors S are concurrently switched. In general, when the light emission thyristors are switched and changed to an on-state, the main current flows between the anodes and the cathodes, thereby lowering the output voltage of the driving circuit to supply the gate signal. Accordingly, when the gate signals inputted to the anodes c of the plurality of switch thyristors S are different from each other in timing and the switch thyristor 3 to which the gate signal has been first inputted is switched to allow the main current to flow therein, the switch thyristor S to which the gate signal is lately inputted may be not switched due to the lack of the voltage of the gate signal. Therefore, by applying the gate signal through the current-limiting resistors RI connected to the anodes c of the switch thyristors S, it is possible to suppress the decrease in output voltage of the driving circuit, thereby satisfactorily switching the plurality of switch thyristors.

The configuration of the light emitting element array chip 1 according to this embodiment will be described specifically now.

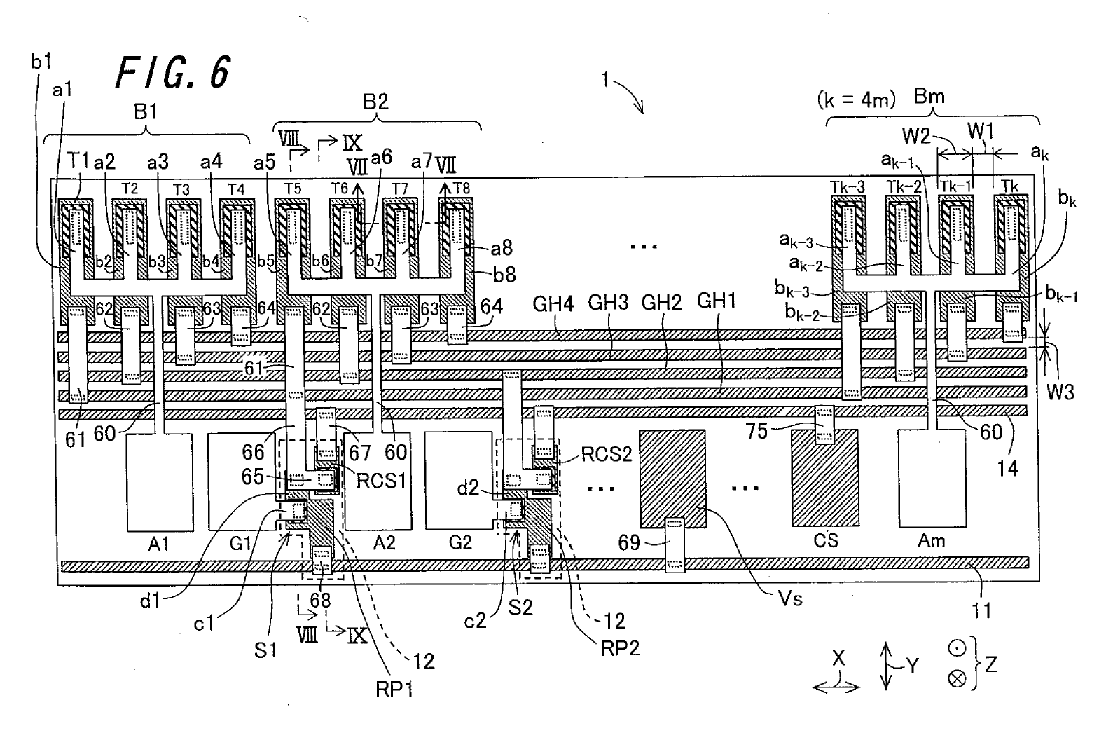

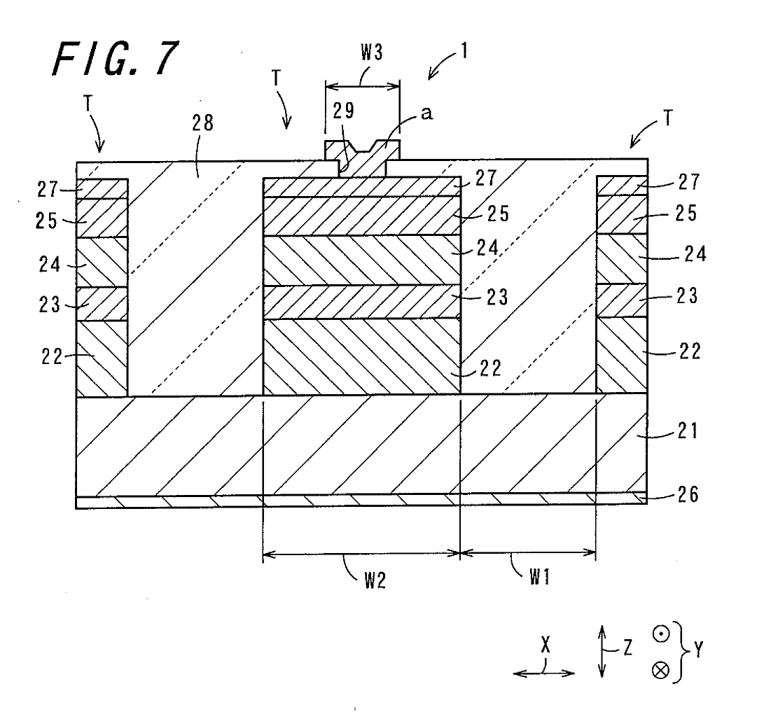

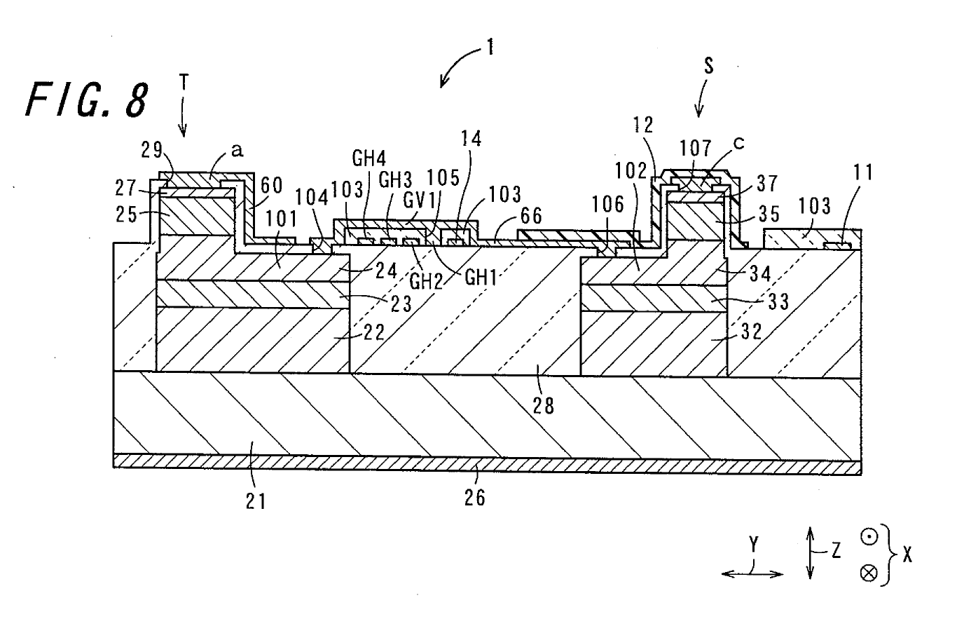

FIG. 6 is a partial plan view illustrating a basic configuration of the light emitting element array chip 1 according to the first embodiment. FIG. 7 is a partial sectional, view illustrating a basic configuration of the light emitting element array chip 1 as viewed from line VII-VII of FIG. 6. FIG. 8 is a partial sectional view illustrating a basic configuration of the light emitting element array chip 1 as viewed from line VIII-VIII of FIG. 6. Further, FIG. 6 shows the plan view of the light emitting element array chip 1 arranged in the state where the light emission direction of the light emitting thyristors T is toward the front of the drawing paper surface. The horizontal gate lines GH1 to GH4, a power supply line 11, a selection signal transmission line 14, a power supply bonding pad Vs, the selection signal input terminal CS, the light emitting thyristors T, the switch thyristors S, the pull-up resistors RP, and the CS resistors RCS are hatched for the purpose of easy understanding.

The plurality of light emitting thyristors T of the light emitting element array chip 1 are arranged with a gap W1 therebetween. The light emitting thyristors T are exposing light emitting elements. In this embodiment, the light emitting thyristors T are arranged in a line with a constant gap. In the following description, the arrangement direction X of the light emitting thyristors T may be described simply as an arrangement direction X. The direction parallel to the light emission direction of the light emitting thyristors T is described as a thickness direction Z and the direction perpendicular to the arrangement direction X and the thickness direction Z is described as a width direction Y. The light emitting thyristors T are formed to emit light having a wavelength of 600 nm to 800 nm.

Since the light emitting thyristor T is formed of an emitting thyristor having the PNPN structure, it can be formed with a simple structure in which a P-type semiconductor and an N-type semiconductor are alternately stacked, thereby easily manufacturing the device. As described above, when the light omission signal is applied to the anodes a1 to ak in the state where the threshold voltage is lower than the voltage of the light emission signal by applying the control signal to the gate electrodes b1 to bk, the light emitting thyristors T emit light.

The light emitting thyristors T1 to Tk are classified into the light emitting element blocks B1 to Bm and the anodes a of the light emitting thyristors T belonging to the same light emitting element block B are connected to the bonding pad as the common light emission signal input terminal A. The bonding pad as the light emission signal input terminal A may be simply described as a light emission signal bonding pad A. In this embodiment, the light emission signal bonding pad A corresponds to the third bonding pad. In this embodiment, four light emitting thyristors T corresponding to the number of horizontal gate lines GH form one light emitting element block B. For example, when the light emitting thyristors T are numbered with first to k-th numbers according to the order of from one end to the other end in the arrangement direction X of the light emitting thyristors T and the light emitting element blocks B are numbered with first to m-th numbers according to the order of from the one end to another end in the arrangement direction, a connecting portion 60 is located between the anodes a of all the (4i₆−3)-th to 4i₆-th light emitting thyristors T (4i₆−3) to T4i₆ belonging to the i₆-th light emitting element block 3i₆ and the light emission signal bonding pad Ai₆ (wherein to electrically connect them. The anodes a of the light emitting thyristors T, the light emission signal bonding pad A, and the connecting portion 60 are formed integrally at the same time. In this embodiment, preferably, the light emission signal bonding pad A is located opposite to the light emitting thyristors T with the horizontal gate lines GH therebetween in the arrangement direction X of the light emitting thyristors T.

The gap W1 of the light emitting thyristors T in the arrangement direction X and the length W2 of the light emitting thyristors T in the arrangement direction X are determined by the resolution of an image to be formed by an image forming apparatus 87 to be described and to be mounted with the light emitting element array chip 1. For example, when the resolution of the image is 600 dot per inch (dpi), the gap W1 is set to about 24 μm and the length W2 is set to about 18 μm.

The horizontal gate lines GH extend between the one end and another end in the arrangement direction X of the light emitting element array chip 1. The horizontal gate lines GH are arranged with a gap in the width direction Y. In this embodiment, the horizontal gate line GH4, the horizontal gate line GH3, the horizontal gate line GH2, and the horizontal gate line GH1 are sequentially arranged from the side close to the light emitting thyristors T. In this embodiment, the selection signal transmission line 14 to supply the selection signal to the gate electrodes d of the switch thyristor S is located apart from the light emitting thyristors T to be parallel to the horizontal gate line GH1. The selection signal transmission line 14 is connected to the bonding pad as the selection signal input terminal CS through a connection portion 75. The bonding pad as the selection signal input terminal CS may be described simply as a selection signal input terminal CS. In this embodiment, the selection signal bonding pad CS corresponds to the first bonding pad. The gap W3 between the horizontal gate lines GH and between the horizontal gate line GH1 and the selection signal transmission line 14 is selected as such a distance that a short-circuit does not occur between the neighboring horizontal gate lines GH and between the horizontal gate line GH1 and the selection signal transmission line 14, for example, 5 μm.

In this embodiment, the gate electrodes b1 to bk of the light emitting thyristors T include a third semiconductor layer 24 (described later), and form connecting portions 61, 62, 63, and 64 between the gate electrodes and any of the horizontal gate lines GH1 to GH4. Here, when the light emitting thyristors T are numbered with first to k-th numbers according to the order of from one end to the other end in an arrangement direction of the light emitting thyristors T, and the light emitting element blocks B are numbered with first to m-th numbers according to the order of from one end to the other end in the arrangement direction, regarding a (4i₆−3)-th to a 4i₆-th light emitting thyristor T belonging to an i₆th light emitting element block Bi₆ in the arrangement direction (1≦i₆≦m), the connecting portion 61 is formed between the gate electrode of the (4i₆−3)-th light emitting thyristor T4i₆−3 and the first horizontal gate line GH1, the connecting portion 62 is formed between the gate electrode of the (4i₆−2)-th light emitting thyristor T4i₆−2 and the second horizontal gate line GH2, the connecting portion 63 is formed between the gate electrode of the (4i₆−1)-th light emitting thyristor T4i₆−1 and the third horizontal gate line GH3, and the connecting portion 64 is formed between the gate electrode of the 4i₆-th light emitting thyristor T4i₆ and the fourth horizontal gate line GHQ. Furthermore, the connecting portion 60 is formed between the anodes a of all of the light emitting thyristors T belonging to the i₆th light emitting element block Bi₆ and an i₆th light emission signal input terminal Ai₆ in the arrangement direction (1≦i₆≦m). When the light emitting thyristors T belonging to the same light emitting element block B are connected to different horizontal gate lines GH in this manner, the light emitting thyristors T can be dynamically driven as described above.

The switch thyristor S is preferably located in a space between the light emission signal bonding pads A. Since one bonding pad to supply the light emission signal is provided in one light emitting element block B including the plurality of light emitting thyristors T, the space can be generated between the light emission signal bonding pads A and the switching elements, etc. can be located effectively using the space. The bonding pads as the gate signal input terminals G to supply the gate signal to the anodes c of the switch thyristors S are located using the spaces generated between the above-mentioned bonding pads. The bonding pads as the gate signal input terminals G may be described simply as the gate signal bonding pads G. In this embodiment, the gate signal bonding pads G correspond to the second bonding pad. The anodes c and the gate signal bonding pads G are integrally formed. Accordingly, when the switch thyristors S are provided, the total size of the light emitting element array chip can be prevented from increasing therewith, thereby configuring a small-sized light emitting element array chip. The number n of switch thyristors S is equal to the number of horizontal gate lines GH and n=4 in this embodiment. The CS resistors RCS are also located close to the switch thyristors S using the spaces generated between the bonding pads as the light emission signal input terminals A.

In this embodiment, the gate electrode d of the switch thyristor S is formed of the third semiconductor layer 34 described later. Connecting portions 65 are formed between the gate electrodes d of the switch thyristors S and the CS resistors RCS and connecting portions 66 are formed between the gate electrodes d and the corresponding horizontal gate lines GH to electrically connect them. The connecting portions 65 connecting the gate electrodes d to the CS resistors RCS and the connecting portions 66 connecting the gate electrodes d to the horizontal gate lines GH are integrally formed. Further, the CS resistors RCS are formed using the sheet resistance of the semiconductor layer and a connecting portion 67 is formed between the CS resistors RCS and the selection signal transmission line 14.

The pull-up resistor RP is formed integrally with the switch thyristor S using a part of the semiconductor layer forming the switch thyristor S. The pull-up resistor RP is formed using the sheet resistance of the semiconductor layer. A connecting portion 68 is formed between a part of the pull-up resistor RP and the power supply line 11 and the supply voltage Vcc is applied to the connecting portion 68 of the pull-up resistor.

The power supply line 11 is located in parallel to the horizontal gate lines GH, and, in this embodiment, is located on the side away from the horizontal gate lines GH with the light emission signal bonding pads A interposed therebetween. The power supply line 11 is electrically connected via a connecting portion 69 to a bonding pad to which the supply voltage Vcc is applied. The bonding pad to which the supply voltage Vcc is applied may be simply referred to as the power supply bonding pad vs.

The anodes a of the light emitting thyristors T, the anodes c of the switch thyristors S, the horizontal gate lines GH, the selection signal transmission line 14, the power supply line 11, the connecting portions 60 to 69, the light emission signal bonding pads A, the gate signal bonding pads G, the selection signal bonding pad CS, and the power supply bonding pad Vs are formed of conductive materials such as metal or alloy. Specifically, the bonding pads are formed of gold (Au), alloy (AuGe) of gold and germanium, alloy (AuZn) of gold and zinc, nickel (Ni), and aluminum (Al).

Further, in the light emitting element array chip 1 shown in FIG. 6, a light-blocking film 12 is located as a light-blocking portion on the surfaces (on the opposite side of the substrate) of the switch thyristors S. The switch thyristors S emits light at the time of switching, similarly to the light emitting thyristors T, but the emission of light thereof is not necessary and thus the light-blocking film is used to prevent the emitted light from entering the light emitting thyristors T to changing the threshold value of the light emitting thyristors T. The light-blocking film 12 is formed of a material not transmitting the emitted light to cover the surface. When proper interlayer insulating films are formed, a gold (Au) film used for the horizontal gate lines GH can be suitably used as the interlayer insulating film. It is effective that the switch thyristors S and the light emitting thyristors T are located as apart as possible from each other, and as shown in the plan view of FIG. 6, it is also effective that the light emitting thyristors T are located on one side of the horizontal gate lines GH and the switch thyristors S are located on the other side.

Note that the above-Mentioned current-limiting resistor RI may be added in a preferable configuration, but is not used in the plan view of the light emitting element array chip 1 shown in FIG. 6.

The configuration of the light emitting element array chip 1 will be further described now in detail, with reference to FIGS. 7 to 9.

The light emitting thyristors T have a structure in which a first semiconductor layer 22, a second semiconductor layer 23, a third semiconductor layer 24, and a fourth semiconductor layer 25, and an ohmic contact layer 27 are sequentially stacked on one surface of a substrate 21 in the thickness direction Z. Here, one conductive type of P type and N type is used in the first semiconductor layer 22 and the third semiconductor layer 24 and the other conductive type is used in the second semiconductor layer 23 and the fourth semiconductor layer 25, whereby a thyristor structure of NPNP or PNPN is formed. The same conductive type of semiconductor as the fourth semiconductor layer 25 is used in the ohmic contact layer 27.

In this embodiment, since the switch thyristor S is formed at the same time as forming the light emitting thyristors T, the layer structures thereof are equal to each other. Specifically, the switch thyristor S are formed by sequentially stacking a first semiconductor layer 32, a second semiconductor layer 33, a third semiconductor layer 34, and a fourth semiconductor layer 35, and an ohmic contact layer 37 on the same surface of the substrate 21 on which the light emitting thyristors T are formed. In the following description, the explanation of the light emitting thyristors T is true in the switch thyristors S.

In this embodiment, the substrate 21 is formed of a semiconductor substrate having the same conductive type as the first semiconductor layer 22. A counter electrode 26 is formed on the entire surface opposite to the surface of the substrate 21 on which the semiconductor layers 22 to 25 are formed in the thickness direction Z. The counter electrode 26 is formed of a conductive material such as metal or alloy. Specifically; the counter electrode 26 is formed of gold (Au), alloy (AuGe) of gold and germanium, and alloy (AuZn) of gold and zinc. The counter electrode 26 is used as a common electrode of the light emitting thyristors T.

In this embodiment, the conductive type of the first semiconductor layer 22 and the third semiconductor layer 24 is the N type, and the conductive type of the second semiconductor layer 23 and the fourth semiconductor layer 25 is the P type. Accordingly, the cathodes of the light emitting thyristors T and the switch thyristors S are connected to the counter electrode 26 as the common electrode, and the N-gate electrode is used as the gate electrodes. When the counter electrode 26 is grounded and thus the cathode potential is made to be 0 V, a positive power supply can be used as the power supply to apply a voltage or current to the anodes a of the light emitting thyristors T, which it is preferable.

An insulating layer 28 is formed along the surfaces of the light emitting thyristors T and the switch thyristors S and is also formed between the light emitting thyristors T and the switch thyristors 5, whereby the light emitting thyristors T and the switch thyristors S are electrically insulated from each other by the insulating layer 28. The insulating layer 2B is formed of a resin material having an electrical insulating property, a light transmitting property, and a flatness property. For example, a resin material such as polyimide and benzocyclobutene (BCE) transmitting 95% or more of the light emitted from the light emitting thyristors T is used

A through-hole 29 is formed in a part of the portion of the insulating layer 28 to cover the surface of the ohmic contact layer 27 (a side apart from the substrate). A part of the anode a is formed in the through-hole 29 to contact with the ohmic contact layer 27. The through-hole 29 is formed at the center of the arrangement direction X of the light emitting thyristor T so that the center of the light emitting thyristor T in the width direction Y is exposed from the insulating layer 28. The current from the anode a can be efficiently supplied to the center portion of the light emitting thyristor T to allow the light emitting thyristor T to emit light. In the light emitting thyristor T, light is emitted mainly in the vicinity of the boundary between the third semiconductor layer 24 and the fourth semiconductor layer 25 and in the area close to the third semiconductor layer 24.

The length W3 of the anode a of the light emitting thyristor T in the arrangement direction X is equal to or less than ⅓ of the length W2 in the arrangement direction X of the light emitting thyristors T. The anode a covers a part of the light emitting thyristor T in the light emission direction, but does not block the light emitted from the light emitting thyristor T as much as possible, by selecting the length W3 as described above.

The materials of the substrate 21, the semiconductor layers 22 to 25, and the ohmic contact layer 27 will be further described specifically now.

The substrate 21 is a semiconductor substrate from which crystals can grow and which is made of III-V group compound semiconductor or II-VI group compound semiconductor, and is formed of a semiconductor material such as gallium arsenide (GaAs), Indium phosphide (InP), gallium phosphide (GaP), silicon (Si), and germanium (Ge).

The first semiconductor layer 22 is formed of a semiconductor material such as gallium arsenide (GaAs), aluminum gallium arsenide (AlGaAs), and indium gallium phosphide (InGaP). It is preferable that the carrier density of the first semiconductor layer 22 is about 1×10¹⁸ cm⁻³.

The second semiconductor layer 23 is formed of a semiconductor material such as aluminum gallium arsenide (AlGaAs) and gallium arsenide (GaAs). As the semiconductor material of the second semiconductor layer 23, a material having an energy gap equal to the energy gap of the semiconductor material of the first semiconductor layer 22 or smaller than the energy gap of the semiconductor material of the first semiconductor layer 22 is selected. It is preferable that the carrier density of the second semiconductor layer 23 is about 1×10¹⁷ cm⁻³.

The third semiconductor layer 24 is formed of a semiconductor material such as aluminum gallium arsenide (AlGaAs) and gallium arsenide (GaAs). As the semiconductor material of the third semiconductor layer 24, a material having an energy gap equal to the energy gap of the semiconductor material of the second semiconductor layer 23 or smaller than the energy gap of the semiconductor material of the second semiconductor layer 23 is selected. It is preferable that the carrier density of the third semiconductor layer 24 is about 1×10¹⁸ cm⁻³. By forming the third semiconductor layer 24 out of the semiconductor material such as aluminum gallium arsenide (AlGaAs) and gallium arsenide (GaAs), it is possible to obtain high inner quantum efficiency as a light emitting element.

The fourth semiconductor layer 25 is formed of a semiconductor material such as aluminum gallium arsenide (AlGaAs) and gallium arsenide (GaAs). As the semiconductor material of the fourth semiconductor layer 25, a material having an energy gap equal to the energy gap of the semiconductor material of the second semiconductor layer 23 and the third semiconductor layer 24 or bigger than the energy gap of the semiconductor material of the second semiconductor layer 23 and the third semiconductor layer 24 is selected. It is preferable that the carrier density of the fourth semiconductor layer 25 is about 1×10¹⁸ cm⁻³.

The ohmic contact layer 27 is a semiconductor layer having the same conductive type as the fourth semiconductor layer 25 formed of the semiconductor material such as gallium arsenide (GaAs) and indium gallium phosphide (InGaP) and is formed for ohmic contact with the anode wiring E. It, is preferable that the carrier density of the ohmic contact layer 27 is about 1×10¹⁹ cm⁻³ or more.

The first semiconductor layer 22, the second semiconductor layer 23, the third semiconductor layer 24, the fourth semiconductor layer 25, and the ohmic contact layer 27 can be sequentially stacked and formed on the substrate 21 by the use of an epitaxial growth method such as molecular beam epitaxial growth method and a chemical vapor deposition (CVD) method. Thereafter, the light emitting thyristors T and the switch thyristors S are formed by performing a patterning and etching process using photolithography. Accordingly, since the light emitting thyristors T and the switch thyristors S are concurrently formed in a series of manufacturing processes, the semiconductor layers of the switch thyristors S and the light emitting thyristors T have the same layer structure. As a result, both the switch thyristors S and the light emitting thyristors T have the light emitting function and the switch function, but the switch thyristors S use only the switch function. In this way, it is possible to simply manufacture the thyristors having a stable structure with the same structure, thereby reducing the manufacturing cost.

The insulating layer 28 is formed by spin-coating the manufactured semiconductor layers with a resin material such as polyimide, hardening the resultant structures, and then performing a patterning and etching process using photolithography to form through-holes 29 and 30 necessary for connection between the electrodes and the light emitting thyristors T.

As shown in FIG. 8, in the shape in the width direction Y of the light emitting thyristor T, the ends of the first semiconductor layer 22, the second semiconductor layer 23, and the third semiconductor layer 24 in the light emitting thyristor T close to the horizontal gate line GH protrude toward the horizontal gate line GH more than the ends of the fourth semiconductor layer 25 and the ohmic contact layer 27 close to the horizontal gate line GH to form a to-be-connected portion 101 to the horizontal gate line GH. The length of the to-be-connected portion 101 in the arrangement direction X is equal to the above-mentioned length W2. The portion of the third semiconductor layer 24 constituting the to-be-connected portion 101 is smaller in thickness than the portion on which the fourth semiconductor layer 25 is stacked. This is because the portion should be over-etched so as not to leave the fourth semiconductor layer 25 at the time of exposing the surface of the third semiconductor layer 24 to form the to-be-connected portion 101 in the etching process.

In the shape in the width direction Y of the switch thyristor S, similarly, the ends of the first semiconductor layer 32, the second semiconductor layer 33, and the third semiconductor layer 34 in the switch thyristor S close to the horizontal gate line GH protrude toward the horizontal gate line GH more than the ands of the fourth semiconductor layer 35 and the ohmic contact layer 37 close to the horizontal gate line GH to form a to-be-connected portion 102 to the horizontal gate line GR. For the over-etching, the thickness of the portion forming the to-be-connected portion 102 in the third semiconductor layer 34 is set to be smaller than the thickness of the portion on which the fourth semiconductor layer 35 is stacked.

The insulating layer 28 is formed along the surface of the light emitting thyristor T and the switch thyristor S and is also formed between the light emitting thyristor T and the switch thyristor S, whereby the light emitting thyristor T and the switch thyristor S are electrically insulated from each other by the insulating layer 28. The horizontal gate line GH and the selection signal transmission line 14 are formed on the surface of the insulating layer 28 formed between the light emitting thyristor T and the switch thyristor S and an insulating layer 103 is additionally formed along the surfaces thereof. The power supply line 11 is formed on the surface of the insulating layer 28 apart from the horizontal gate line with the switch thyristor S interposed therebetween, and the insulating layer 103 is additionally formed along the surface.

In the formed insulating layers 28 and 103, through-holes 104 and 105 are formed in the portions stacked on the connecting portion 101 of the light emitting thyristor T and the surface (on the opposite side of the substrate) of the horizontal gate line GH. The connecting portion 61 electrically connecting the third semiconductor layer 24 (corresponding to the gate electrode b) of the light emitting thyristor T to the horizontal gate line GH is stacked on the portions of the through-holes 104 and 105 and the portions of the insulating layers 28 and 105 interposed between the through-holes 104 and 105. Through-holes 105 sand 106 are formed in the portions of the insulating layers 28 and 103 stacked on the connecting portion 102 of the switch thyristor S and the surface of the horizontal gate line GH (on the opposite side of the substrate). The connecting portion 66 electrically connecting the third semiconductor layer 34 (corresponding to the gate electrode d) of the switch thyristor 3 to the horizontal gate line GH is stacked on the portions of the through-holes 105 and 106 and the portions of the insulating layers 28 and 103 interposed between the through-holes 105 and 106. As shown in FIG. 8, when the through-hole 105 formed in the portion of the insulating layer 103 on which the horizontal gate line GH is stacked is common, common, the connecting portions 61 and 66 are integrally formed.

Further, as described above, in the insulating layer 28 stacked on the light emitting thyristor T, the through-hole 29 is formed in a part of the portion stacked on the surface (on the opposite side of the substrate) of the ohmic contact layer 27. A part of the anode a is formed in the through-hole 29 to contact with the ohmic contact layer 27. The anode a is formed integrally with the connecting portion 60 to the light emission signal input terminal A. The connecting portion 60 covers the fourth semiconductor layer 25 of the light emitting thyristor T and a part of the end of the ohmic contact layer 27 close to the horizontal gate line GH, and is stacked on a part of the surface (on the opposite side of the substrate) of the insulating layer 28 stacked on the connecting portion 101 located in the third semiconductor layer 24. In the insulating layer 28 stacked on the switch thyristor S, the through-hole 107 is formed in a part of the portion stacked on the surface (on the opposite side of the substrate) of the ohmic contact layer 37. A part of the anode c is formed in the through-hole 107 to contact with the ohmic contact layer 37.

Furthermore, the switch thyristor S is covered with the light-blocking film 12. One end in the width direction Y of the light-blocking layer 12 covers the fourth semiconductor layer 35 of the switch thyristor S and the end of the ohmic contact layer 37 opposite to the light emitting thyristor T. Another end in the width direction. Y of the light-blocking film 12 covers the connecting portion 102 of the third semiconductor layer 34 of the switch thyristor S and extends to the vicinity of the center portion between the selection signal transmission line 14 and the switch thyristor S.

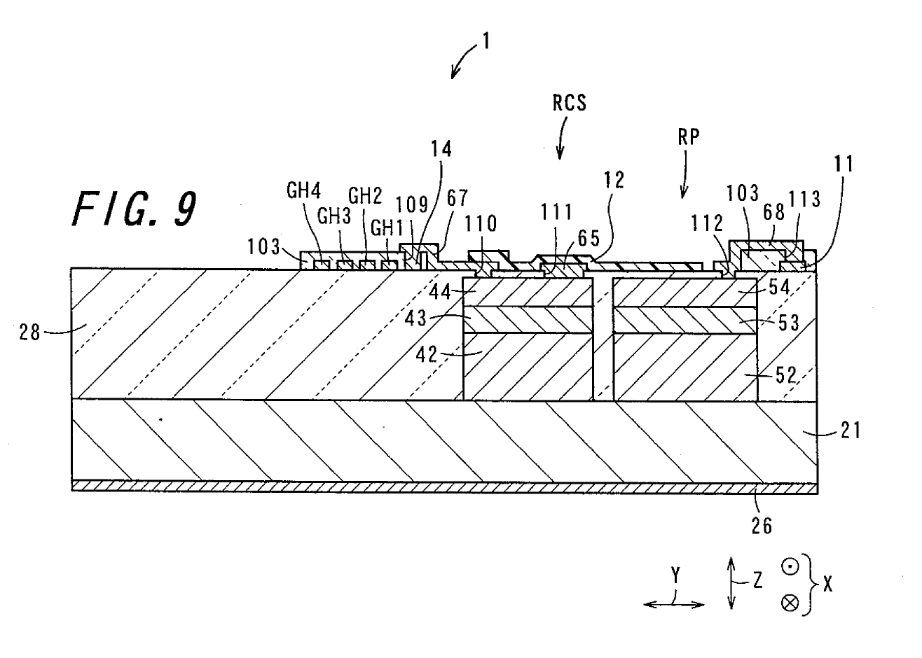

FIG. 9 is a partial sectional view illustrating a basic configuration of the light emitting element array chip 1 as viewed from section line IX-IX of FIG. 6.

The CS resistor RCS and the pull-up resistor RP may use, as a thin film resistor, a semiconductor layer including any of the semiconductor layers 22 to 25 and 32 to 35 forming the light emitting thyristor T and the switch thyristor S. In this embodiment, the pull-up resistor RF uses a semiconductor thin film including a first semiconductor layer 52, a second semiconductor layer 53, and a third semiconductor layer 54, and the CS resistor RCS uses a first semiconductor layer 42, a second semiconductor layer 43, and a third semiconductor layer 44. In this embodiment, the CS resistor RCS and the pull-up resistor RP are simultaneously formed when the semiconductor layers 22 to 25 and 32 to 35 and ohmic contact layers 27 and 37 forming the light emitting thyristor T and the switch thyristor S are formed, and thus, an additional manufacturing step is not necessary.

The surface of an end portion on one side in a width direction Y of the third semiconductor layer 44 forming the CS resistor RCS is connected to one end of a connecting portion 65 that connects the gate electrode d of the switch thyristor S and the CS resistor RCS, and corresponds to one end of the CS resistor RCS. Furthermore, an end portion on the other side in the width direction Y of the third semiconductor layer 44 forming the CS resistor RCS is connected to one end of a connecting portion 67 that connects a selection signal transmission line 14 and the CS resistor RCS, and corresponds to another end of the CS resistor RCS.

The etching step of determining the total thickness of the first semiconductor layer 42, the second semiconductor layer 43, and the third semiconductor layer 44 forming the CS resistor RCS, and the first semiconductor layer 52, the second semiconductor layer 53, and the third semiconductor layer 54 forming the pull-up resistor RP is performed simultaneously with the formation of the connected portions 101 and 102. Accordingly, the thickness of the CS resistor RCS and the pull-up resistor RP is the same as the thickness of the connected portions 101 and 102.

In FIG. 9, the insulating layer 28 is formed along the surface of the CS resistor RCS and the pull-up resistor RP, and is formed also between the CS resistor RCS and the pull-up resistor RP, and thus, the CS resistor RCS and the pull-up resistor RP are electrically insulated from each other by the insulating layer 28. As described above, the horizontal gate lines GH, the selection signal transmission line 14, and the power supply line 11 are formed on the surface of the insulating layer 28, and the insulating layer 103 is formed along the surface of these constituent elements.

Portions of the formed insulating layers 28 and 103 layered on the selection signal transmission line 14 and the surface (on the opposite side of the substrate) of the end portion on the other side in the width direction Y of the third semiconductor layer 44 forming the CS resistor RCS have through-holes 109 and 110, and the connecting portion 67 for electrically connecting these holes is located therein. Furthermore, a portion of the insulating layer 28 layered on the surface (on the opposite side of the substrate) of the end portion on one side in the width direction Y of the third semiconductor layer 44 forming the CS resistor RCS has a through-hole 111, and the connecting portion 65 for connection with the gate electrode d of the switch thyristor S is located therein. Furthermore, portions of the formed insulating layers 28 and 103 layered on the pull-up resistor RP and the power supply line 11 have through-holes 112 and 113, and the connecting portion 68 for electrically connecting these holes is located therein.

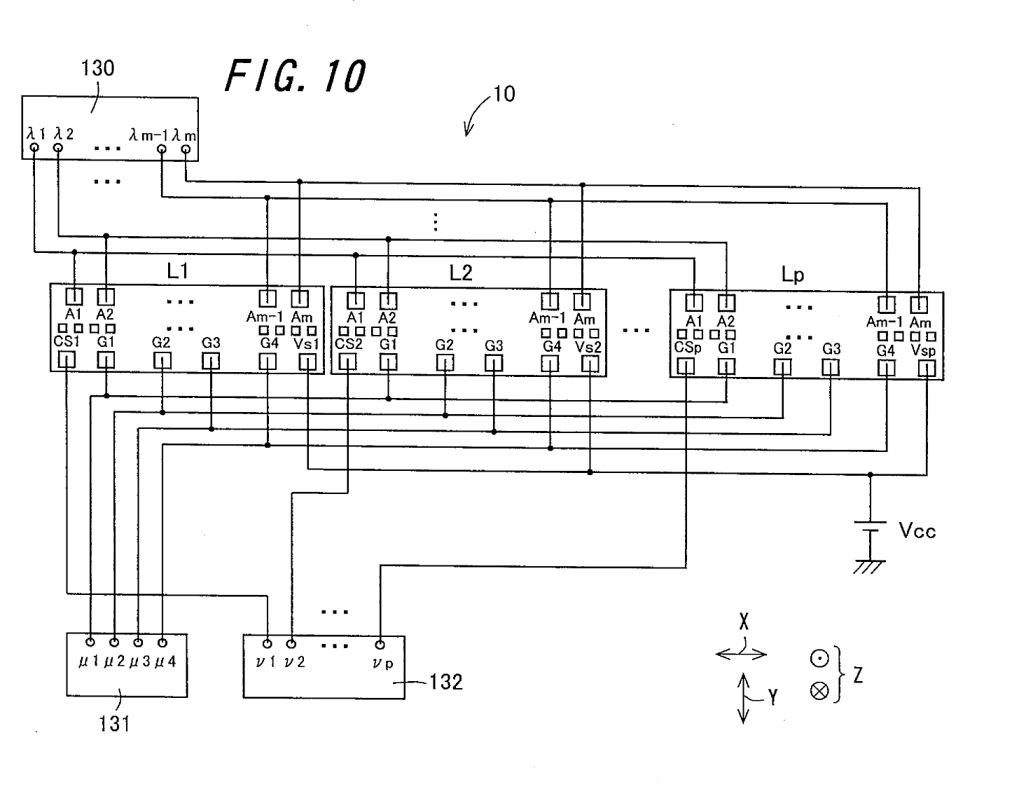

FIG. 10 is a block diagram schematically illustrating a light emitting device 10 according to an embodiment of the invention. The light emitting device 10 includes a plurality of light emitting element array chips L1, L2, . . . , Lp−1, and Lp (wherein p is a positive integer of 2 or more), a light emission signal driving IC (Integrated Circuit) 130 to supply the light emission signal as a driving circuit for the light emitting element array chips L1 to Lp, a gate signal driving IC 131 to supply the gate signal, and a selection signal driving IC 132 to supply the selection signal. The driving ICs output image information under the control of a control portion 96 to be described later. The light emitting element array chips L1 to Lp are simply described as the light emitting element array chip L, when they are collectively referred to or when the unspecified ones are mentioned. The light emitting element array chip L may be described simply as the array chip L. In this embodiment, the light emitting element array chip 1 according to the first embodiment shown in FIG. 1 is employed as the array chips L. The selection signal driving IC 132 corresponds to the first driving circuit, the gate signal driving IC 131 corresponds to the second driving circuit, and the light emission signal driving IC 130 corresponds to the third driving circuit.

The light emitting elements T of the each array chip L are arranged in a line in the arrangement direction X and the array chips are mounted on a circuit board so that the light emission directions of the light emitting elements T are parallel to each other. However, the circuit board is not shown in FIG. 10. The light emission signal driving IC 130, the gate signal driving IC 131, and the selection signal driving IC 132 are mounted on the circuit board. Wiring patterns connecting the output terminals of the driving ICs 130 to 132 to the bonding pad of the each array chip L are formed on the circuit board, and the wiring patterns and the bonding pads are connected to each other by bonding wires.

As described above, the light emitting element array chip 1 of the first embodiment shown in FIGS. 1 and 5 includes m light emission signal bonding pads A, one selection signal bonding pad CS, and four gate signal bonding pads G. Furthermore, the power supply bonding pad Vs for connecting a positive power supply applied to another end of the pull-up resistor RP (on the side opposite to the side to which the gate electrode d of the switch thyristor S is connected) is necessary, and is shown in FIG. 10. Here, in the case of this embodiment in which p array chips are mounted as shown in FIG. 10, when the array chips L are numbered with first to p-th numbers according to the order of from one end to the other end in the arrangement direction X of the light emitting elements T constituting the array chips, the selection signal bonding pad CS of an i₁₀-th array chip L (1≦i₁₀≦p) is referred to as a selection signal bonding pad CSi₁₀. In the case where the selection signal bonding pads CS1 to CSp of an unspecified array chip L are referred to, that constituent element may be simply referred to as a selection signal bonding pad CS.

The light emission signal driving IC 130 includes the same number of (m) light emission signal output terminals λ1 to λm as the number of light emission signal bonding pads A1 to Am of the respective array chips L. The light emission signal output terminals λ1 to λm may be described simply as the light emission signal output terminals λ, when they are collectively referred to or the unspecified ones are mentioned. The connection between the light emission signal bonding pads A and the light emission signal output terminals λ is made by commonly using a wiring between the different array chips. In this embodiment in which the p array chips are mounted, when the light emission signal bonding pads λ1 to λm are numbered with first to m-th numbers, respectively, and the light emission signal output terminals A1 to An are numbered with first to m-th numbers according to the order of from the one end to another end in the arrangement direction X of the light emitting elements T constituting the respective array chips L, the i₈-th light emission signal bonding pads Ai₈ (wherein 1≦i₈≦m) of the p array chips are electrically connected to each other and are further electrically connected to the i₈-th light emission signal output terminals λi₈.

The gate signal driving IC 131 includes the same number (four) of gate signal output terminals μ1 to μ4 as the number of the gate signal bonding pads G1 to G4 of the array chips L. The gate signal output terminals μ1 to μ4 may be described simply as the gate signal output terminals μ, when they are collectively referred to or when unspecified ones are mentioned. The connection between the gate signal bonding pads G and the gate signal output terminals μ is made by commonly using a wiring line between the different array chips. In this embodiment in which the p array chips are mounted, when the gate signal bonding pads G1 to G4 are numbered with first to fourth numbers, respectively, and the gate signal output terminals μ1 to μ4 are numbered with first to fourth numbers according to the order of from the one end to another end in the arrangement direction X of the light emitting elements T constituting the respective array chips the i₉-th light emission signal bonding pads Gi₉ (wherein 1≦i₉≦4) of the p array chips are electrically connected to each other and are further electrically connected to the i₉-th gate signal output terminals μi₉.

The selection signal driving IC 132 includes the same number of (p) selection signal output terminals ν1 to vp as the number of array chips L. The selection signal output terminals ν1 to νp may be described simply as the selection signal output terminals ν, when they are collectively referred to or when the unspecified ones are mentioned. The connections between the selection signal bonding pads CSi₁₀ and the selection signal output terminals ν are individually connected to the respective array chips. In this embodiment in which the p array chips are mounted, when the array chips are numbered with first to p-th numbers, respectively, and the selection signal output terminals ν1 to νp are numbered with first to p-th numbers according to the order of from the one end to another end in the arrangement direction X of the light emitting elements T constituting the respective array chips L, the selection signal bonding pad CSi₁₀ of the i₁₀-th array chip L and the i₁₀-th selection signal output terminal νi₁₀ are electrically connected to each other (wherein 1≦i₁₀≦p).

As described above, since the selection signal bonding pads CS and the selection signal output terminals ν of the array chips L are individually connected, the selection signal driving IC 132 sequentially outputs the selection signal to the selection signal bonding pads CS of the array chips L to sequentially make the array chips L in the selected state. On the other hand, since the wiring lines of the array chips L and the gate signal driving IC 131 are shared with each other, for example, the gate signal outputted from the i₉-th gate signal output terminal μi₉ (wherein 1≦i₉≦4) is inputted to the i₉-th gate signal bonding pads Gi₉ (wherein 1≦i₉≦4) of all the array chips L, and is inputted to the anodes ci₉ of the i₉-th switch thyristor Si₉ of all the array chips L. However, among the i₉-th switch thyristor Si₉ of the array chips L, only the array chip L in the selected state by the input of the selection signal is switched. Among the light emitting thyristors T connected to i₉-th horizontal gate line GHi₉ of the array chip L in the selected state, the light emitting thyristors T belonging to the light emitting element block B to which the light emission signal is inputted from the light emission signal driving IC 130 emit light.

In this way, by sequentially switching the array chips L in the selected state, it is possible to stably carry out time-division driving operation in which the gate signal driving IC 131 and the light emission signal driving IC 130 are commonly used among the plurality of light emitting element arrays. Accordingly, it is possible to reduce the number of driving ICs and the number of layers in the circuit board on which the driving ICs are mounted and to reduce the rear of the circuit board on which the light emitting element arrays and the driving ICs are mounted, thereby embodying a small-sized light emitting device which stably operates.

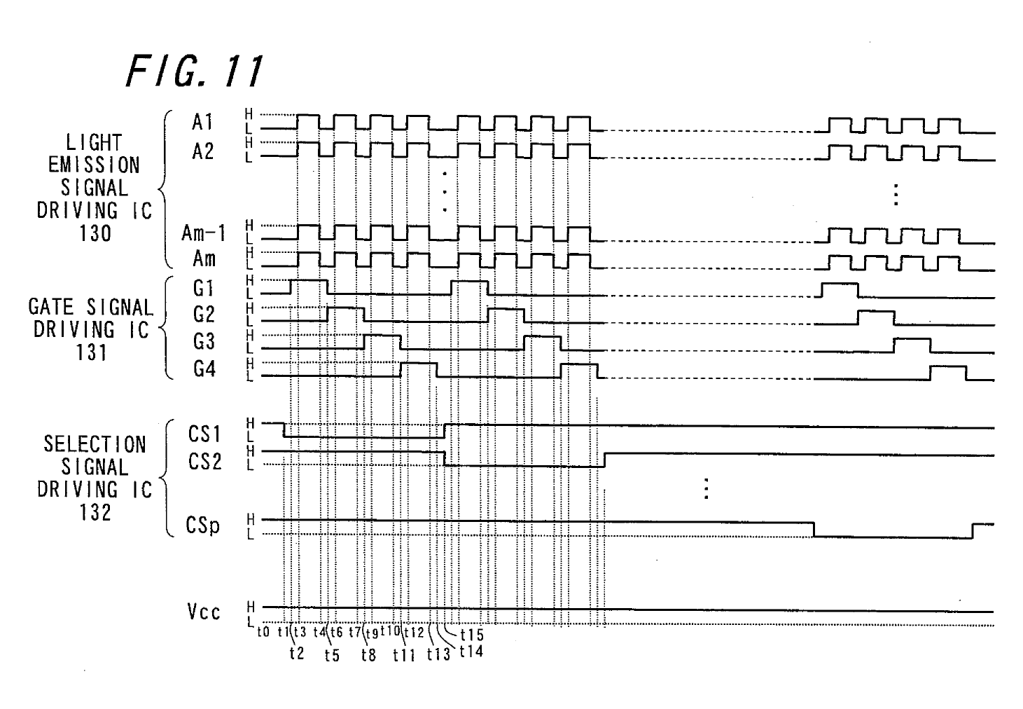

FIG. 11 is a timing chart showing the operation of a light emitting device 10. The horizontal axis indicates the time that has elapsed from a reference time, and the vertical axis indicates the signal level as a voltage or a current. In FIG. 11, the waveforms of signals (the light emission signal, the gate signal, and the selection signal) outputted from the respective signal output terminals (the light emission signal output terminal λ, the gate signal output terminal μ, and the selection signal output terminal ν) of the light emission signal driving IC 130, the gate signal driving IC 131, and the selection signal driving IC 132 are shown. Furthermore, the waveform of the supply voltage Vcc applied to another end of the pull-up resistor RP (on the side opposite to the side to which the gate electrode d of the switch thyristor S is connected) is also shown. Here, in FIG. 11, the reference numerals of the bonding pads (signal input terminals) connected to the respective signal output terminals are used as the reference numerals of the output waveform.

In this embodiment, the light emission signal driving IC 130 outputs a constant current of 5 mA in the case of a high (H) level, and of 0 mA in the case of a low (L) level. The gate signal driving IC 131 outputs a constant current of 1 mA in the case of a high (H) level, and of 0 mA in the case of a low (L) level. The selection signal driving IC 132 outputs a constant voltage of 5 V in the case of a high (H) level, and of 0 V in the case of a low (L) level. Furthermore, the supply voltage Vcc applied to another end of the pull-up resistor (on the aide opposite to the side to which the gate electrode d of the switch thyristor S is connected) is 5 V.

Hereinafter, the operation of the light emitting device 10 will be described in order of time with reference to FIG. 11. At the time t0, the selection signal is at a high (H) level, and thus; all of the array chips are not in a selected state. At the time t1, the selection signal inputted into the first array chip L1 is set to a low (L) level, and thus, the first array chip L1 is turned to a selected state. At the time t2, a signal at a high (H) level is inputted into the first gate signal input terminal G1 of each array chip L. Then, only in the first array chip L1 in a selected state, the first switch thyristor S1 is switched and shifts to an on-state, and the potential of the horizontal gate line GH1 connected to the gate electrode d1 of the switch thyristor S1 is turned to a substantially low level (0 V). Nest, at the time t3, the light emission signal is inputted into the light emission signal input terminals A1 to Am of each array chip. Then, in the first array chip L1 in a selected state, the light emitting thyristor T connected to the first horizontal gate line GH1 emits light. At the time t4, the light emission signal returns to a low (L) level, and thus, the light is turned off. Next, at the time t5, the gate signal inputted into the first gate signal input terminal G1 returns to a low (L) level, and the gate signal inputted into the second gate signal input terminal G2 is turned to a high (H) level. Then, only in the first array chip L1 in a selected state, the second switch thyristor S2 is switched and shifts to an on-state. At the times t6 to t7, the light emission signal is inputted again to the light emission signal input terminals A1 to Am of each array chip. Then, in the first array chip L1 in a selected state, the light emitting thyristor T connected to the second horizontal gate line GH2 emits light. Hereinafter, in a similar manner, at the times t8 to t11, the gate signal inputted into the third gate signal input terminal G3 is turned to a high (H) level, and thus, in the first array chip L1 in a selected state, the third switch thyristor S3 is switched and shifts to an on-state. In this state, at the times t9 to t11, the light emission signal is inputted again to the light emission signal input terminals A1 to Am of each array chip, and thus, in the first array chip L1 in a selected state, the light emitting thyristor T connected to the third horizontal gate line GH3 emits light. Furthermore, at the times t11 to t14, the gate signal inputted into the fourth gate signal input terminal G4 is turned to a high (H) level, and thus, in the first array chip L1 in a selected state, the fourth switch thyristor S4 is switched and shifts to an on-state. In this state, at the times t12 to t13, the light emission signal is inputted again to the light emission signal input terminals A1 to Am of each array chip, and thus, in the first array chip L1 in a selected state, the light emitting thyristor T connected to the fourth horizontal gate line GH4 emits light. At the time t15, the gate of the switch thyristor S of the first array chip L1 shifts to a high (H) level, the selected state of the first array chip L1 ends, and the selection signal inputted into the selection signal input terminal CS2 of the second array chip L2 shifts to a low (L) level at the time t15, and the second array chip L2 enters a selected state.

In this way, by sequentially applying the selection signals to the array chips from the first array chip to the other array chips to sequentially select the array chips, it is possible to time-divisionally drive the array chips L. By applying the gate signals to the switch thyristors from the first switch thyristor to the other switch thyristors, it is possible to time-divisionally drive each array chip L.

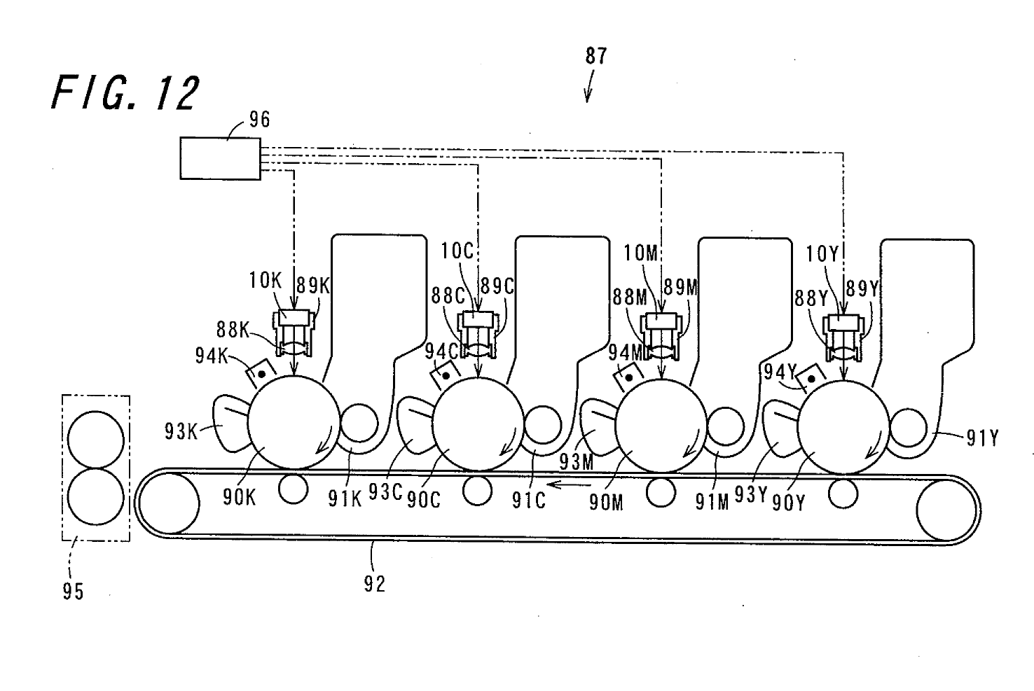

FIG. 12 is a side view illustrating a basic configuration of an image forming apparatus employing the light emitting device 10 including the light emitting element array chip 1 according to this embodiment.

The image forming apparatus 87 is an electrophotographic image forming apparatus, in which the light emitting devices 10Y, 10M, 10C, and 10K are used as exposure devices for a photoreceptor drum 90. The light emitting devices 10Y, 10M, 10C, and 10K are mounted on the circuit board mounted with the driving ICs (the light emission signal driving IC 130, the gate signal driving IC 131, and the selection signal driving IC 132).

The image forming apparatus 87 is an apparatus of a tandem type in which images of four colors consisting of Y (yellow), M (magenta), C (cyan), and K (black) are formed, and schematically includes, four light emitting devices 10Y, 10M, 10C, and 10K, lens arrays 88Y, 88M, 88C, and 88K that are light condensing portions, first holders 89Y, 89M, 89C, and 89K that hold circuit substrates on which the light emitting devices 10Y, 10M, 100, and 10K and driving ICs 130, 131, 132, and 136 are mounted and the lens arrays 88, four photosensitive drums 90Y, 90M, 90C, and 90K, four developer supplying portions 91Y, 91M, 91C, and 91K, a transfer belt 92 that is a transfer portion, four cleaners 93Y, 93M, 93C, and 93K, four charging devices 94Y, 94M, 94C, and 94K, a fixing portion 95, and a control portion 96.

The light emitting devices 10Y, 10M, 10C, and 10K are driven by the driving ICs on the basis of the color image information of the colors. For example, lengths in the arrangement direction X of the four light emitting devices 10Y, 10M, 100, and 10K are selected, for example, to be in the range of 200 mm to 400 mm.

The light from the light emitting thyristors T of the light emitting devices 10Y, 10M, 10C, and 10K is condensed and applied on the photoreceptor drums 90Y, 90M, 90C, and 90K through the lens arrays 88. The lens arrays 88 include a plurality of lenses located in optical axes of the light emitting elements and the lenses integrally form the lenses.

The circuit board mounted with the light emitting devices 10Y, 10M, 10C, and 10K and the lens arrays 88 are held by the first holders 89. The light emitting thyristors T and the lens arrays 88 are positioned by the first holders 89 so that the light emission direction of the light emitting thyristors T is substantially matched with the optical axis direction of the lenses of the lens arrays 88.

The photoreceptor drums 90Y, 90M, 90C, and 90K are formed by forming a photosensitive layer onto the surface of a cylindrical substrate. Electrostatic latent image forming positions where electrostatic latent images are formed with the light from the light emitting devices 10Y, 10M, 10C, and 10K are set on outer peripheral surfaces thereof.

In the peripheries of the photoreceptor drums 90Y, 90M, 90C, and 90K, toward the downstream in a rotation direction from the electrostatic latent image forming positions, developer supplying portions 91Y, 91M, 91C, and 91K to supply developers to the exposed photoreceptor drums 90Y, 90M, 90C, and 90K, the transfer belt 92, cleaners 93Y, 93M, 93C, and 93K, and the charging devices 94Y, 94M, 94C, and 94K are sequentially arranged. The transfer belt 92 to transfer the images formed on the photoreceptor drums 90 with the developers onto a recording sheet is located in common to four photoreceptor drums 90Y, 90M, 90C, and 50K.

The photoreceptor drums 90Y, 90M, 90C, and 90K are held by a second holder and the second holder and the first holder 89 are fixed relative to each other. A rotation axis direction of the photoreceptor drums 90Y, 90M, 90C, and 90K is substantially matched with the arrangement direction X of the light emitting devices 10Y, 10M, 10C, and 10K.

The recording sheet is transported by the transfer belt 92 and the recording sheet having images formed thereon with the developers is transported to the fixing portion 95. The fixing portion 95 fixes the developer transferred to the recording sheet. The photoreceptor drums 90Y, 90M, 90C, and 90K are rotated by rotation driving portion.

The control portion 96 gives the clock signal and the image information to the driving ICs 130, 131, 132, and 136, and controls the rotation driving portion for rotationally driving the photoreceptor drums 90Y, 90M, 90C, and 90K, the developer supplying portion 91Y, 91M, 91C, and 91K, the transfer portion 92, the charging devices 94Y, 94M, 94C, and 94K, and the fixing portion 95.

In the image forming apparatus 87 having the above-mentioned configuration, since it is determined on the basis of the gate signal transmitted through the horizontal gate lines GH connected to the gate electrodes g in which the main current does not flow whether the light emitting elements should be switched to a light emission state or a non-light emission state, it is possible to reduce the width of the gate signal transmission lines formed on the circuit board on which the light emitting devices 10Y, 10M, 10C, and 10K are mounted, thereby reducing the size of the circuit board. Since the main current is not switched depending on the gate signal driving IC 131, the IC capacity can be reduced, thereby accomplishing the decrease in size and cost.

As described above, in the light emitting element array chip 1 according to this embodiment, the switch thyristors S provided as the switching element operate so as to give the gate signal to the light emitting thyristors T only at the time selected by the selection signal. Accordingly, when the plurality of light emitting element array chips 1 are arranged and driven, the time-division driving operation can be performed by commonly using the driving ICs and wiring lines to supply the light emission signal and the gate signal without connecting the driving ICs to all the light emitting element array chips 1, thereby obtaining a basic operational advantage that the time-division driving operation can be performed with the small number of driving ICs and wiring lines.

Further, when the plurality of light emitting element blocks B in which the anodes a are used in common to the plurality of light emitting thyristors T are arranged and the plurality of light emitting element blocks 13 share the horizontal gate lines GH, the plurality of light emitting element blocks B can be time-divisionally driven in one light emitting element array chip 1. As a result, since the number of horizontal gate lines GH to be connected to the driving ICs can be reduced, it is possible to provide a light emitting device that can perform a time-division driving operation with the small number of driving ICs by using the driving ICs having the small number of output ports for the gate signal.

Furthermore, when the bonding pads A, G, and CS to supply the light emission signal, the gate signal, and the selection signal are arranged in the arrangement direction X of the light emitting elements, one light emission signal bonding pad A is provided for one light emitting element block B and thus a space is formed between the light emission signal bonding pads A provided for the neighboring light emitting element blocks B. Accordingly, the switch thyristors S and the like can be arranged to effectively utilize the space. As a result, in spite of providing the switch thyristors S and the like, it is possible to prevent the increase in size of the light emitting element array chip, thereby providing a small-sized light emitting element array chip.

Moreover, since the switching elements and the light emitting elements include the light emission thyristors, it is possible to configure a logic circuit to select the light emitting element array chip 1 to whish the gate signal should be inputted with a simple configuration without using a complex semiconductor device such as a NAND gate or an inverter. Accordingly, it is possible to accomplish the simple design and to simplify the manufacturing processes.

Further, when the pull-up resistor R2, the CS resistor RCS, and the like are used, there is an advantage in that the potential of the gate of the switch thyristor S can be freely set by selecting the resistance of the CS resistor RCS and the pull-up resistor RP. Furthermore, even in the cape where a diode, a thyristor, and the like are used instead of the CS resistor RCS, similar time-division driving operation can be performed, but, in this case, a diode and a thyristor connected to the gate of the switch thyristor S in an off-state are in an on-state. Accordingly, in the case where a light emitting element array chip 1 including four switch thyristors S are subjected to time-division driving operation, three switch thyristors S are in an off-state, three diodes or thyristors are in an on-state, and thus, the duty ratio of diodes or thyristors used instead of the CS resistor RCS increases, and the reliability of the equipment is lowered. However, in the light emitting element array chip 1 of this embodiment, the CS resistor RCS is used, and thus, only one of the switch thyristors S is in an on-state, the duty ratio of the switching element is lowered, and the reliability of the equipment is improved.

Moreover, when the current-limiting resistor RI is connected between the gate signal bonding pad G and the anode c of the switch thyristor S and the plurality of switch thyristors S are concurrently switched to an on-state for the purpose of high speed operation, it is possible to stably secure the potential of the anodes c of the switch thyristors S without any decrease in signal voltage of the gate signal at the time of first switching, in spite of the slight difference in switching timing. Accordingly, since the plurality of switch thyristors can be satisfactorily switched, it is possible to drive the plurality of light emitting element array chips 1 at the same time-division timing and thus it is advantageous in high speed operation.

Further, when the semiconductor layers forming the switch thyristors S and the semiconductor layers forming the light emitting thyristors T are formed so as to having the same layer structure, it is possible to manufacture the light emitting thyristors T and the switch thyristors S at the same time by the use of the same processes. Accordingly, in the configuration according to the invention employing the switch thyristors S in addition to the light emitting thyristors T as the light emitting elements, the manufacturing processes are not complicated, thereby providing a light emitting element array advantageous in manufacturing.

Furthermore, when a metal thin film is formed as a light-blocking portion on the surface of the switch thyristor S, it is advantageous in that the light emitted from the switch thyristor S can be prevented from entering the light emitting thyristors T to change the threshold value of the light emitting thyristors T.

Moreover, since the light emitting device has a small size and high reliability in stable operation by employing the light emitting element array chip 1 having the above-mentioned configuration, it is possible to provide an image forming apparatus that can stably form an excellent image.

According to the invention, as described above, it is possible to provide a light emitting element array that can perform a time-division driving operation with the small number of driving ICs, a small-sized light emitting device employing the light emitting element array, and an image forming apparatus having the light emitting device.

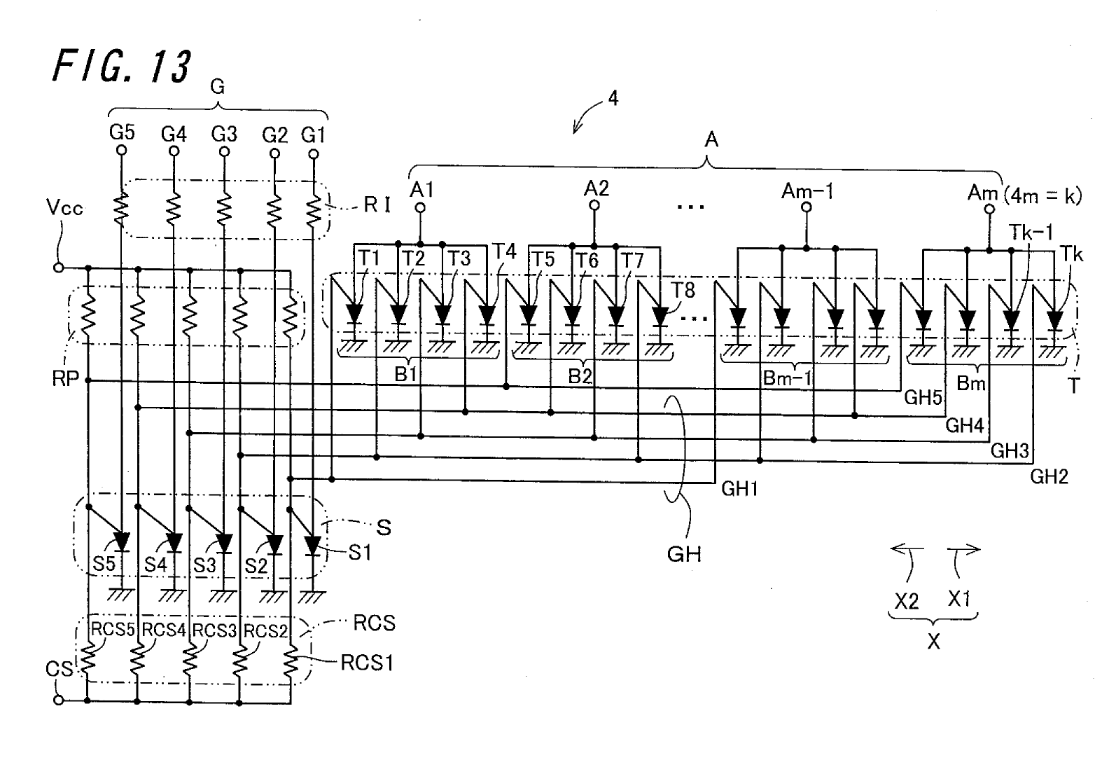

FIG. 13 is a schematic equivalent circuit diagram showing a light emitting element array chip 4 according to a second embodiment of the invention. This light emitting element array chip is different from the light emitting element array chip 1 of the first embodiment shown in FIG. 1 in that, in FIG. 13, the number of switch thyristors S is n=5, and thus, the number of horizontal gate lines GH is equal to this number, that is, n=5, but the number of light emitting thyristors T constituting a light emitting element block B is smaller than that number by 1, that is, n−1=4. Furthermore, the connection between the horizontal gate lines GH and the light emitting thyristors T constituting the light emitting element block B is characteristic. Here, the other constituent elements in the configuration are the same as those in the foregoing embodiment, and thus, the same constituent elements are denoted by the same reference numerals, and a description thereof is omitted.

In FIG. 13, the direction from the side close to the switch thyristors S to the side apart therefrom in the arrangement direction X of the light emitting thyristors T is defined as an X1 direction and the opposite direction thereof is defined as the X2 direction. The X1 direction and the X2 direction constitute the X direction. Here, the light emitting element blocks are numbered with first to m-th numbers in the X1 direction and the light emitting thyristors T constituting the respective light emitting element blocks are numbered with first to (n−1)-th numbers in the X1 direction. In addition, the n horizontal gate lines GH are numbered from first to n-th numbers in a predetermined order.

In this embodiment, in the odd-numbered light emitting element blocks, the i₁-th light emitting thyristor T in the light emitting element block is connected to the j₁-th horizontal gate line GHj₁ so as to satisfy i₁=j₁ (wherein 1≦i₁≦n−1 and 1≦i₁≦n−1). In the even-numbered light emitting element blocks, the i₂-th light emitting thyristor T in the light emitting element block is connected to the j₂-th horizontal gate line GHj₂ so as to satisfy i₂+j₂=n+1 (wherein 1≦i₂≦n−1 and 2≦j₂≦n).

In this case, the light emitting thyristor T adjacent in the X direction to the light emitting thyristor T connected to the first horizontal gate line GH1 is connected to the second horizontal gate line GH2. In addition, the light emitting thyristor T adjacent in the X direction to the light emitting thyristor T connected to the j₃-th horizontal gate line GHj₃ (wherein 2≦j₃≦n−1) is connected to one of the (j₃−1)-th or (j₃+1)-th horizontal gate line. The light emitting thyristor T adjacent in the X direction to the light emitting thyristor T connected to the n-th horizontal gate line GHn is connected to the (n−1)-th horizontal gate line GHn−1. Accordingly, when the gate signal (the second signal) is inputted to the switching elements of the light emitting element array in the selected state and the control signal is outputted sequentially in a time-division mariner from the first horizontal gate line GH1 to the n-th horizontal gate line GHn−1, the difference in timing when the light emitting thyristors T adjacent to each other emit light can be reduced. Since the adjacent light emitting thyristors T are not connected to the same control signal transmission line, it is possible to suppress the adjacent light emitting thyristors T from emitting light at the same time.

When the light emitting device configured to include the light emitting element array according to the invention is thereby used as an exposure device for exposing a photoreceptor drum, the great difference in timing when the adjacent light emitting thyristors emit light is suppressed, whereby a discontinuous point is not generated at the exposure positions on the photoreceptor drum. Since the concurrent light emission of the adjacent light emitting thyristors T is prevented, the difference in light emission of heat is suppressed when the light emitting thyristors T emit light, thereby making constant the light emission characteristic with the variation in temperature of the light emitting thyristors T. Since the interference of light emitted from the adjacent light emitting thyristors T can be prevented, it is possible to expose the photoreceptor drum with high precision. As a result, in the image forming apparatus employing the light emitting element array according to this embodiment, it is possible to obtain a recorded image with high image quality.

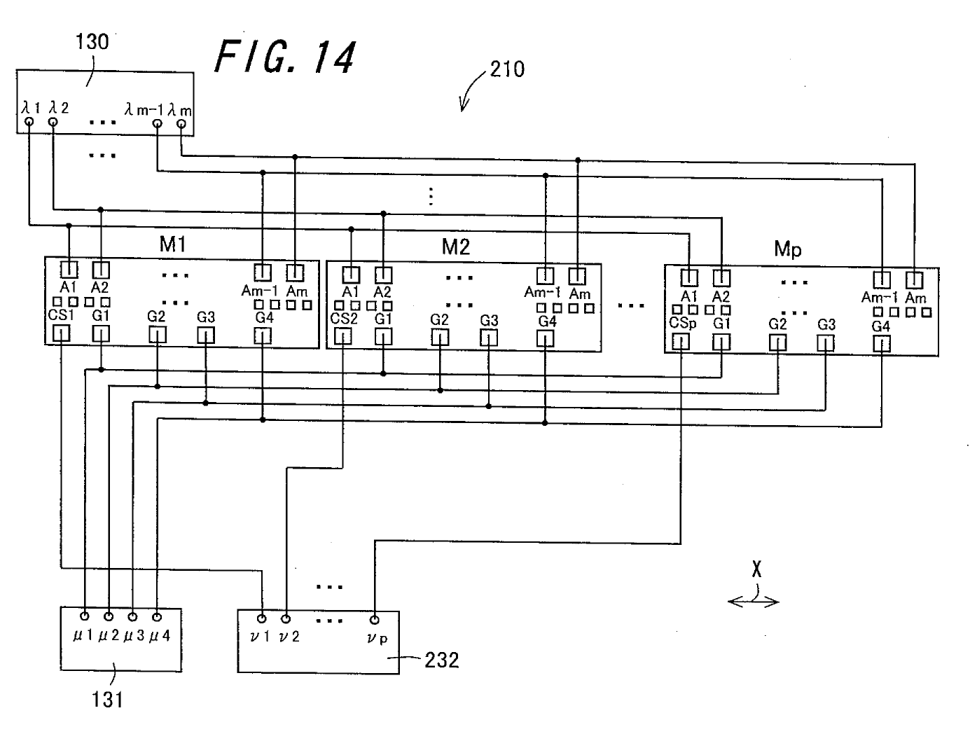

FIG. 14 is a block circuit diagram schematically showing a light emitting device 210 according to another embodiment of the invention. The light emitting device 210 of this embodiment is similar to the above-described light emitting device 10, and is different from the light emitting device 10 only in the configuration of part of the light emitting element array chip and the configuration of the selection signal driving IC. The other constituent elements in the configuration are the same as those in the foregoing embodiment, and thus, the same constituent elements are denoted by the same reference numerals, and a description thereof may be omitted.

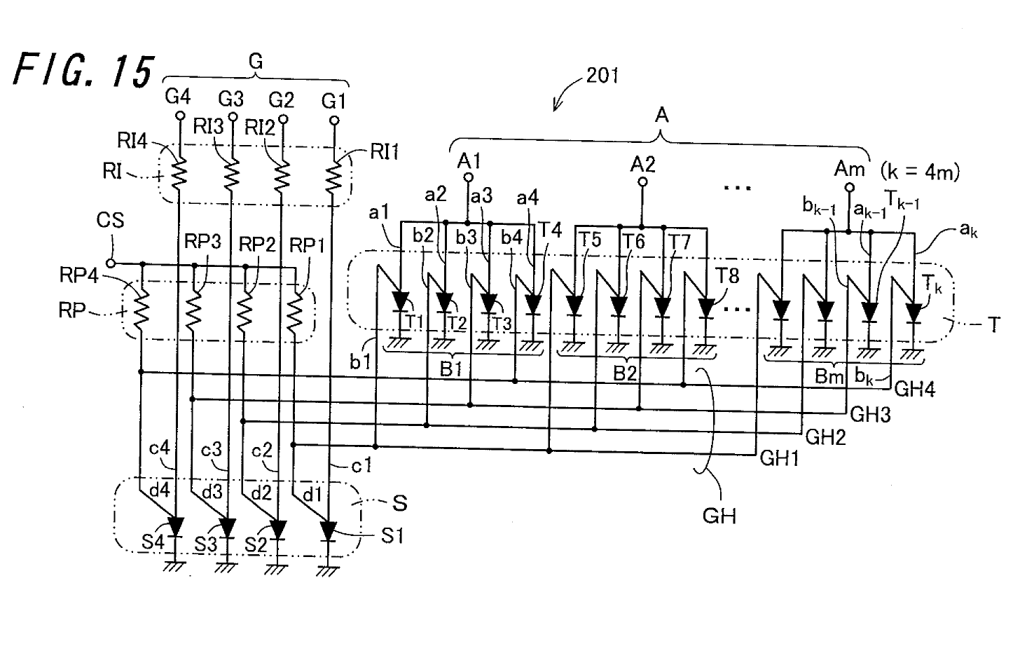

The light emitting device 210 includes a light emitting element array portion including a plurality of light emitting element array chips M1, M2, . . . , Mp−1, and Mp (the symbol p is a positive integer of 2 or more), and, as driving circuits of the light emitting element array chips M1 to Mp, the light emission signal driving IC (integrated circuit) 130, the gate signal driving IC 131, and a selection signal driving IC 232 that supplies a selection signal. Each driving IC outputs image information according to the above-described control portion 96. In the case where the light emitting element array chips M1 to Mp are collectively referred to, or in the case where each unspecified constituent element is referred to, that constituent element may be simply referred to as a light emitting element array chip M. Furthermore, the light emitting element array chip M may be simply referred to as an array chip M. In this embodiment, a light emitting element array chip 201 (described later) shown in FIG. 15 is used as each array chip M. Here, the selection signal driving IC 232 corresponds to the first driving circuit.

The light emitting elements T of the each array chip M are arranged in a line in the arrangement direction X and the array chips are mounted on a circuit board so that the light emission directions of the light emitting elements T are parallel to each other. However, the circuit board is not shown in FIG. 14. The light emission signal driving IC 130, the gate signal driving IC 131, and the selection signal driving IC 232 are mounted on the circuit board. Wiring patterns connecting the output terminals of the driving ICs 130, 131, and 232 to the bonding pad of the each array chip M are formed on the circuit board, and the wiring patterns and the bonding pads are connected to each other by bonding wires.

FIG. 15 is a schematic equivalent circuit diagram showing the light emitting element array chip 201 included in the light emitting device 210. The light emitting element array chip 201 is similar to the above-described light emitting element array chip 1, and, more specifically, has a configuration in which the CS resistors RCS and the selection signal input terminal CS are removed from the light emitting element array chip 1, and thus, the constituent elements corresponding to those of the light emitting element array chip 1 are denoted by the same reference numerals, and a description thereof may be omitted. In the light emitting element array chip 201, the portion that is the supply voltage input terminal Vcc in the light emitting element array chip 1 functions as a selection signal input terminal CS.

Although not shown, the light emitting element array chip 201 has a configuration in which the selection signal transmission line 14, the CS resistors RCS, the selection signal input terminal CS, and the connecting portions 67 and 75 are removed from the light emitting element array chip 1 shown in FIGS. 6 to 9. In the light emitting element array chip 201, the power supply line 11 in FIGS. 6 to 9 functions as a selection signal transmission line, and the power supply bonding pad Vs functions as a selection signal input terminal CS.

The light emitting device 210 of this embodiment is characterized in that the function of the CS resistors RCS arranged in the above-described light emitting device 10 is located in the selection signal driving IC 232 that is a driving IC.

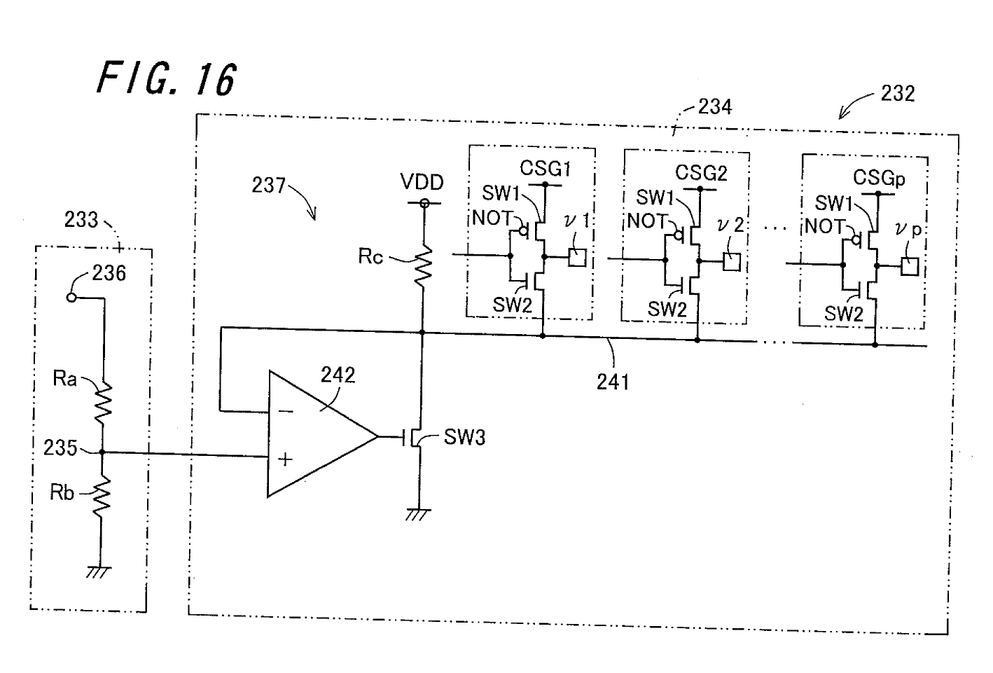

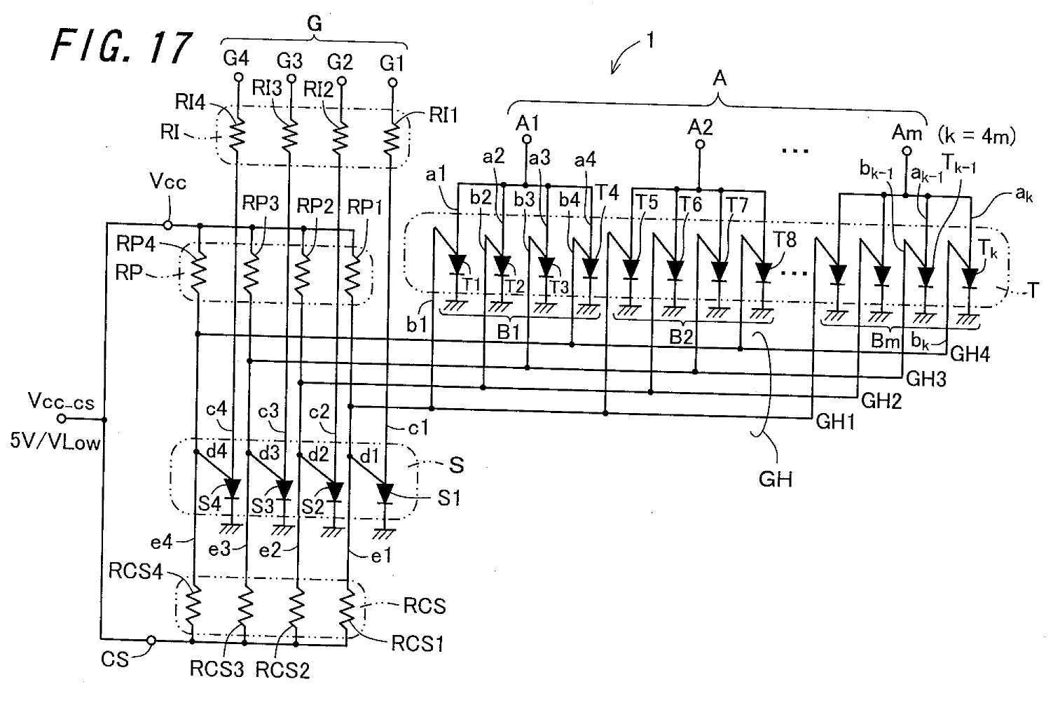

FIG. 16 is a diagram showing an example of the configuration of part of the selection signal driving IC 232. The selection signal driving IC 232 includes a setting portion 233 that sets the potential at a high level and at a low level of a selection signal that is a first signal having a high level and a low level. In this embodiment, the setting portion 233 sets the potential at the low level of the selection signal. Furthermore, the selection signal driving IC 232 includes an output portion 234 that can output a selection signal at a signal level according to the setting portion 233. The setting portion 233 is a first signal level-setting portion.

The setting portion 233 includes a plurality of resistors R that are connected in series and that output a voltage for setting the potential at the low level of the selection signal from a connecting portion 235 positioned at a point in the resistors R. In this embodiment, the plurality of resistors R are composed of two resistors Ra and Rb. An end 236 on one side of the resistor Ra is provided with a predetermined potential Vp, and the connecting portion 235 between the resistor Ra and the resistor Rb is connected to a non-inverting input terminal of an operational amplifier (described later). The predetermined potential Vp is set to, for example, 5 V. Furthermore, an end on the other side of the resistor Rb is connected to the ground. The potential of the ground is selected to be, for example, 0 V.

The output portion 234 includes voltage-switching portions CSG1 to CSGp that respectively have the selection signal output terminals vi to vp respectively corresponding to the light emitting element array chips M1 to Mp, and a voltage-generating portion 237 that is connected to the setting portion 233 and that generates a voltage at the low level of the selection signal according to the voltage outputted from the connecting portion 235 of the setting portion 233. In the case where a plurality of voltage-switching portions CSG1 to CSGp are collectively referred to, or in the case where each unspecified constituent element is referred to, that constituent element may be simply referred to as a voltage-switching portion CSG.

The voltage-switching portion CSG includes two switching elements Sw1 and Sw2, and an inverter NOT. The switching elements Sw1 and Sw2 are constituted by a field effect transistor. The switching elements Sw1 and Sw2 are connected so as to be complementarily turned on and off when a switch drive signal is applied to the voltage-switching portion CSG. More specifically, a predetermined potential Vcsg that is the potential at the high level of the selection signal is applied to the drain of the switching element Sw1, and the drain of the switching element Sw2 is connected to the source of the switching element Sw1. The sources of the switching elements Sw2 are commonly connected to a signal line 241 in the respective voltage-switching portions CSG. The source of the switching element Sw1 and the drain of the switching element Sw2 are connected to the selection signal output terminals ν.

Furthermore, the gate of the switching element Sw1 is connected to the inverter NOT. A switch drive signal is applied to the gate of the switching element Sw1 via the inverter NOT, and the switch drive signal is directly applied to the gate of the switching element Sw2. The switch drive signal is an internal signal of the IC applied from the control circuit of the selection signal driving IC 232. The switch drive signal is a pulse signal, and has a high level portion and a low level portion. When the switch drive signal is at a high level, the first switching element SW1 is not conductive and the second switching element SW2 is conductive. When the switch drive signal is at a low level, the first switching element SW1 is conductive, and the second switching element SW2 is not conductive. The control, circuit of the selection signal driving IC 232 applies the switch drive signal to the voltage-switching portion CSG according to the above-described control portion 96.

The voltage-generating portion 237 includes the signal line 241, an operational amplifier 242, a resistor Rc, and a switching element Sw3. The switching element Sw3 includes a field effect transistor. The inverting input terminal of the operational amplifier 242 is connected to the signal line 241, the non-inverting input terminal is connected to the connecting portion 235, and the output terminal is connected to the gate of the switching element Sw3. The drain of the switching element Sw3 is connected to the signal line 241, and the source is connected to the ground. One end of the resistor Rc is connected to the signal line 241, and another end of the resistor Rc is provided with a predetermined potential VDD. With this sort of circuit configuration, in the voltage-generating portion 237, the voltage of the signal line 241 is set according to the voltage applied to the non-inverting input terminal of the operational amplifier 242.

Based on the above-described switch drive signal, the switching elements Sw1 and Sw2 are complementarily opened and closed, and thus, the predetermined potential Vcsg or the potential of the signal line 241 is applied to the selection signal output terminal ν, and the signal level of the selection signal is set to a high level or a low level. The potential of the signal line 241 is a potential that is lowered to less than the predetermined potential VDD by a voltage obtained by multiplying a current that flows through the resistor Rc by a resistance of the resistor Rc. Accordingly, when the resistance ratio between the resistors Ra and Rb is changed or when the predetermined potential Vd applied to the end 236 on one side of the resistor Ra is changed, the voltage outputted from the connecting portion 235 can be changed, and thus, the signal level can be changed with a simple configuration. Furthermore, for example, when the resistance of resistor Rb is set to 0Ω by providing the voltage-generating portion 237, the selection signal driving IC 232 can be used as an IC that drives the light emitting element array chip 1 shown in FIG. 1, and thus, the versatility can be improved.

A selection signal outputted from this sort of selection signal driving IC 232 has a waveform similar to that of the selection signal outputted from the selection signal driving IC 132, but, in this embodiment, the resistances of the first and the second resistors Ra and Rb and the resistor Rc, the predetermined potential vp, and the predetermined potential VDD are determined such that the potential at the low level of the selection signal is, for example, 2.5 V, and the potential at the high level is, for example, 5 V. The light emitting element array chip 201 operates as indicated by the table of truth values shown in Table 1.

The wiring connections between the light emitting element array chips M1 to Mp, the light emission signal driving IC 130, the gate signal driving IC an, and the selection signal driving IC 232 are similar to those in the light emitting device 10 shown in FIG. 10 described above, and thus, a description thereof is omitted.

In the light emitting device 210 described above, the light emitting element T can selectively emit light as in the above-described light emitting device 10, and thus, the light emitting device 210 can achieve an effect similar to that of the light emitting device 10. Furthermore, in the light emitting device 210, the signal level of the selection signal can be set by the setting portion 233 that is located outside the light emitting element array chip 201, and thus, a CS resistor RCS does not have to be provided, the number of resistor elements can be reduced in the entire apparatus, and the number of power supply lines can be reduced. Furthermore, a current that flows through the selection signal transmission line is reduced, and thus, this selection signal transmission line can be formed thinner, a circuit of alight emitting element array chip can be simplified, and the size of the chip can be reduced. Furthermore, it is sufficient that one setting portion 233 is located in the selection signal driving IC 232 shared by the plurality of light emitting element array chips, and thus, the configuration can be simplified without lowering the overall functionality of the light emitting device compared with the case in which a function similar to that of the setting portion 233 is provided in each light emitting element array chip.

Furthermore, in the light emitting device 210, a current flows through the pull-up resistor RP only when the switch thyristor S is in an on-state, and thus, the amount of current consumed can be lower than that of the above-described light emitting device 10. Furthermore, the setting portion 233 can freely set the signal level of the selection signal, and thus, the degree of freedom in design can be improved.

In this embodiment, the setting portion 233 corresponds to the first signal level-setting portion, but the first signal level-setting portion may include the setting portion 233 and the output portion 234.

Furthermore, in the case where the selection signal driving IC 232 is used as an IC that drives the light emitting element array chip 1 shown in FIG. 1, the setting portion 233 can set the potential at the high level of the selection signal. In this case, for example, the second switching element Sw2 of the voltage-switching portion CSG may be connected to the ground and the first switching element Sw1 may be connected to the signal line 241 such that the potential at the low level is the ground potential.

FIG. 17 shows a circuit diagram for simulating the operational characteristics of the light emitting element array chip 201. In order to simulate the operational characteristics of the light emitting element array chip 201, in the light emitting element array chip 1, a voltage in which the high level is 5 V and the low level is a voltage VLow at a given level was applied between the supply voltage input terminal vcc and the selection signal input terminal CS as shown in FIG. 17, and the operation was observed.

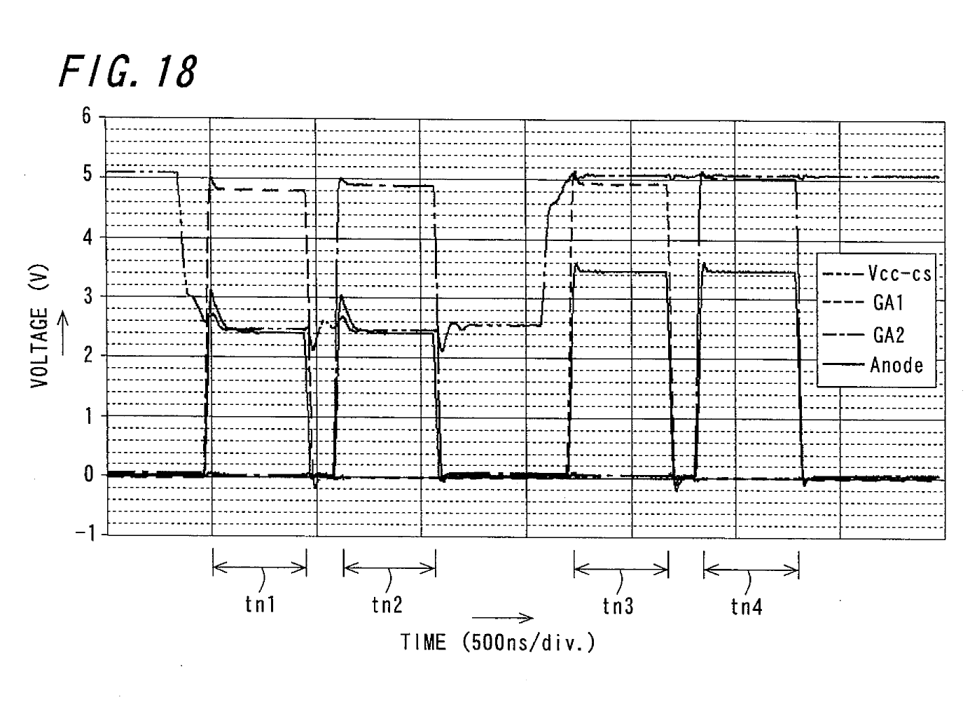

FIG. 18 is a graph showing an example of the operational characteristics of the circuit in FIG. 17. In FIG. 18, the horizontal axis indicates the time (unit: 500 nanoseconds (ns)/div), and the vertical axis indicates the signal level (unit: volt (V)). In FIG. 18, the dashed double dotted line indicates the voltage Vcc-cs applied between the supply voltage input terminal Vcc and the selection signal input terminal CS, the dashed line indicates the potential of the gate signal input terminal G1, the dashed dotted line indicates the potential of the gate signal input terminal G2, and the solid line indicates the potential of the anode of the light emitting thyristors T1 to T4 connected to the light emission signal input terminal A1. Here, measurement was performed on the first light emitting element block 81 and the gate signal input terminals G1 and G2 shown in FIG. 17, but a similar effect can be obtained also for the other elements.

In the measurement of operational characteristics shown in FIG. 18, a current at a high (H) level of 20 mA (in which the drive voltage is approximately 2.4 V) is applied as the light emission signal, and, when the light emission signal is not applied, the level is a low (L) level and no current flows through the light emitting thyristor T (0 V, 0 mA). Furthermore, a voltage at a high (H) level of 5 V is applied as the gate signal to the gate signal input terminal G, and, when the gate signal is not applied, the state is set to a low (L) level and a potential of 0 V is applied. The load resistors RL1 and RL2, the pull-up resistor PR1, and the CS resistor RCS1 are set as shown in FIG. 3, and the resistance of the current-limiting resistor RI used as a preferable embodiment is set to 1000Ω.

Furthermore, in the measurement of operational characteristics shown in FIG. 18, “CSA Delay” is 120 ns, and “GA Delay” is 140 ns. Here, “CSA Delay” refers to the necessary time from when a Vcc-cs signal is turned to a low level to when a GA1 signal is turned to a high level, and refers to the necessary time for the potential of each signal line (signal transmission line) in the light emitting element array chip to be turned to a low level due to a delay according to a time constant. Furthermore, “GA Delay” refers to the necessary time between GA signals (e.g., a time from when GA1 is turned to a low level to when GA2 is turned to a high level). When GA1 is turned to a low level, the potential of the signal transmission line connected to the switching element at GA1 returns from 0 V to a predetermined potential (e.g., 2.5 V), but this return is also delayed according to the time constant, and thus, “GA Delay” refers to the necessary time for the potential of the signal transmission line to return from 0 V to the predetermined potential. Furthermore, the clock frequency is 100 Mega Hertz (MHz).

First, in the time period tn1 shown in FIG. 18, the voltage of the gate signal input terminal G1 is set to a high level (5 V), the voltage applied between the supply voltage input terminal Vcc and the selection signal input terminal CS is set to a low level (2.5 V), and the current that is caused to flow through the light emission signal input terminal A is set to a high level (20 mA). In the time period tn1, a voltage at a high level (5 V) is applied to the anode c1 of the switch thyristor S1, and thus, the switch thyristor S1 shifts to an on-state. Furthermore, a light emission signal at a high level (20 mA) is applied to the anode a1 of the light emitting thyristor T1, and thus, the light emitting thyristor T1 shifts to an on-state and emits light. In the case where the light emitting thyristor T1 is in an on-state in this manner, the potential of the anode of the light emitting thyristor T1 indicated by the solid line is approximately 2.4 V, which is a drive voltage level of the light emitting thyristor T.

Next, in the time period tn2 shown in FIG. 18, the voltage of the gate signal input terminal G2 is set to a high level (5 V), the voltage applied between the supply voltage input terminal Vcc and the selection signal input terminal CS is set to a low level (2.5 V), and the current that is caused to flow through the light emission signal input terminal A is set to a high level (20 mA). In the time period tn2, a voltage at a high level (5 V) is applied to the anode c1 of the switch thyristor S1, and thus, the switch thyristor S2 shifts to an on-state. Furthermore, a light emission signal at a high level (20 mA) is applied to the anode of the light emitting thyristor T2, and thus, the light emitting thyristor T2 shifts to an on-state and emits light. In the case where the light emitting thyristor T2 is in an on-state in this manner, the potential of the anode of the light emitting thyristor T2 indicated by the solid line is approximately 2.4 V, which is a drive voltage level of the light emitting thyristor T.

Next, in the time period tn3 shown in FIG. 18, the voltage of the gate signal input terminal G1 is set to a high level (5 V), the voltage applied between the supply voltage input terminal Vcc and the selection signal input terminal. CS is set to a high level (5 V), and the current that is caused to flow through the light emission signal input terminal A is set to a high level (20 mA). In the time period tn3, even when a voltage at a high level (5 V) is applied to the anode c1 of the switch thyristor S1, the switch thyristor S1 does not shift to an on-state. Furthermore, even when a light emission signal at a high level (20 mA) is applied to the anode of the light emitting thyristor T1, the light emitting thyristor T1 does not shift to an on-state and does not emit light. In the case where the light emitting thyristor T1 is in an off-state in this manner, the potential of the anode of the light emitting thyristor T1 indicated by the solid line is higher than approximately 2.4 V, which is a drive voltage level of the light emitting thyristor T, by approximately 0.7 to 0.8 V.

Next, in the time period tn4 shown in FIG. 18, the voltage of the gate signal input terminal G2 is set to a high level (5 V), the voltage applied between the supply voltage input terminal Vcc and the selection signal input terminal CS is set to a high level (5 V), and the current that is caused to flow through the light emission signal input terminal A is set to a high level (20 mA). In the time period tn4, even when a voltage at a high level (5 V) is applied to the anode c1, of the switch thyristor S1, the switch thyristor S2 does not shift to an on-state. Furthermore, even when a light emission signal at a high level (20 mA) is applied to the anode of the light emitting thyristor T2, the light emitting thyristor T2 does not shift to an on-state and does not emit light. In the case where the light emitting thyristor T2 is in an off-state in this manner, the potential of the anode of the light emitting thyristor T2 indicated by the solid line is higher than approximately 2.4 V, which is a drive voltage level of the light emitting thyristor T, by approximately 0.7 to 0.8 V.

The above-described operational characteristics are similar to those in the case where, in the light emitting device 210, the selection signal is switched between a high level (5 V) and a low level (0 V), and applied to the selection signal input terminal CS. Accordingly, it is seen that, also in the light emitting device 210, only when all three signals consisting of the selection signal, the gate signal, and the light emission signal are at a high level, does the light emitting thyristor T emit light, and, when even only one of the three signals is at a low level, the light emitting thyristor T does not emit light.

Here, the invention is not limited to the foregoing embodiments, and, for example, various modifications and improvements are possible within a range not departing from the gist of the invention. For example, a configuration is possible in which the above-described light emitting device 210 is used instead of the light emitting device 10 in the above-described image forming apparatus 87. This configuration also can achieve a similar effect. Furthermore, the size of the light emitting device can be reduced, and thus, an image of a higher definition can be formed.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

1. A light emitting element array, comprising:
(a) n pieces of switching elements (n is an integer of 2 or more) each comprising a first electrode, a second electrode, and a first control electrode that outputs a control signal when a first signal is inputted into the first electrode and a second signal is inputted into the second electrode;
(b) n pieces of signal transmission lines respectively connected to the first control electrodes; and
(c) a plurality of light emitting elements that each comprises a third electrode, and a second control electrode connected to any one of the n pieces of signal transmission lines, and each emits light when a third signal is inputted into the third electrode and the control signal is inputted into the second control electrode; wherein
each of the n pieces of signal transmission lines is connected to the second control electrode of at least one of the plurality of light emitting elements,
the first electrodes of the n pieces of switching elements are electrically connected to each other,
the n pieces of switching elements and the plurality of light emitting elements each comprises a light emission thyristor having either one of a cathode and an anode thereof as a common electrode, and the n pieces of switching elements each further comprises a first resistor and a second resistor,
(i) when the cathode is the common electrode,
an N gate electrode of the light emission thyristor of each of the n pieces of switching elements is connected to one ends of the first and second resistors,
a positive voltage with reference to the common electrode is applied to another end of the first resistor,
the first electrode is connected to another end of the second resistor,
the second electrode is the anode of the light emission thyristor of each of the n pieces of switching elements,
the third electrode is the anode of the light emission thyristor of each of the plurality of light emitting elements,
the first control electrode is the N gate electrode of the light emission thyristor of each of the n pieces of switching elements, and
the second control electrode is an N gate electrode of the light emission thyristor of each of the plurality of light emitting elements, and
(ii) when the anode is the common electrode,
a P gate electrode of the light emission thyristor of each of the n pieces of switching elements is connected to one ends of the first and second resistors,
a negative voltage with reference to the common electrode is applied to another end of the first resistor,
the first electrode is connected to another end of the second resistor,
the second electrode is the cathode of the light emission thyristor of each of the n pieces of switching elements,
the third electrode is the cathode of the light emission thyristor of each of the plurality light emitting elements,
the first control electrode is the P gate electrode of the light emission thyristor of each of the pieces of switching elements, and
the second control electrode is a P gate electrode of the light emission thyristor of each of the plurality of light elements.

2. The light emitting element array of claim 1, wherein the plurality of light emitting elements comprises a plurality of light emitting element blocks comprising n or less pieces of light emitting elements in which the third electrodes thereof are electrically connected to each other, and
the second control electrodes of the light emitting elements in one of the plurality of light emitting element blocks are connected to respective ones of the n pieces of signal transmission lines which are different with each other.

3. The light emitting element array of 2, wherein the plurality of light emitting elements are arranged in a lane,
each of the plurality of light emitting element blocks is composed of n−1 pieces of light emitting elements (n is an integer of 4 or more),
odd-numbered light emitting element blocks of the plurality of light emitting element blocks, which are numbered according to an order of from one end to the other end in an arrangement direction of the plurality of light emitting elements, each comprises an i₁-th light emitting element which is numbered according to the order of from one end to the other end in the arrangement direction, and the i₁-th light emitting element is connected to a j₁-th signal transmission line so as to satisfy i₁=j₁ (wherein it is an integer of 1 or more and n−1 or less and j₁ is an integer of 1 or more and n−1 or less), and
even-numbered light emitting element blocks of the light emitting element blocks, which are numbered according to an order of from one end to the other end in the arrangement direction of the plurality of light emitting elements, each comprises an i₂-th light emitting element which is numbered according to the order of from one end to the other end in the arrangement direction, and the i₂-th light emitting element is connected to a j₂-th signal transmission line so as to satisfy i₂+j₂=n+1 (wherein i₂ is an integer of 1 or more and n−1 or less and j₂ is an integer of 2 or more and n or less).

4. The light emitting element array of claim 2, further comprising a substrate and bonding pads located on one surface of the substrate, wherein
the plurality of light emitting elements are arranged substantially in a straight line on the one surface of the substrate,
the n pieces of signal transmission lines are located on the one surface of the substrate along the arrangement direction of the plurality of light emitting elements,
the bonding pads are arranged at intervals therebetween along the arrangement direction of the plurality of light emitting elements,
the bonding pads comprises:
a first bonding pad connected to the first electrode;
second bonding pads connected to the respective second electrodes; and
third bonding pads connected to the third electrodes of the light emitting elements in respective ones of the plurality of light emitting element blocks, and a number of the third bonding pads being smaller than that of the plurality of light emitting elements, and
the n pieces of switching elements are located between the adjacent bonding pads.

5. The light emitting element array any one of claims to 4, wherein the second electrodes are respectively connected to third resistors, and the second signal is applied to the second electrodes via the third resistors.

6. The light emitting element array of claim 1, wherein the light emission thyristors of the n pieces of switching elements and the plurality of light emitting elements comprise the same layer structure.

7. The light emitting element of claim 1, further comprising a light-blocking portion or a light-reducing portion for blocking or reducing light emitted from the light emission thyristor of the switching element.

8. A light emitting device, comprising:
the plurality of light emitting element arrays of claim 1;
a first driving circuit that is electrically connected to the first electrodes and that supplies the first signal;
a second driving circuit that is electrically connected to the second electrodes and that supplies the second signal; and
a third driving circuit that is electrically connected to the third signals and that supplies the third signal.

9. A light emitting device, comprising:
a light emitting element array portion comprising a plurality of light emitting element arrays, each comprising,
(a) n pieces of switching elements (n is an integer of 2 or more) each comprising a first electrode, a second electrode, and a first control electrode that outputs a control signal when a first signal is inputted into the first electrode and a second signal is inputted into the second electrode,
(b) n pieces of signal transmission lines respectively connected to the first control electrodes, and
(c) a plurality of light emitting elements that each comprises a third electrode, and a second control electrode connected to any one of the n pieces of signal transmission lines, and each emits light when a third signal is inputted into the third electrode and the control signal is inputted into the second control electrode, wherein
each of the n pieces of signal transmission lines is connected to the second control electrode of at least one of the light emitting elements,
the first electrodes of the n pieces of switching elements are electrically connected to each other,
the n pieces of switching elements and the plurality of light emitting elements each comprises a light emission thyristor having either one of a cathode and an anode thereof as a common electrode, and the n pieces of switching elements each further comprises a resistor,
(i) when the cathode is the common electrode,
an N gate electrode of the light emission thyristor of each of the n pieces of switching elements is connected to one end of the resistor,
the first electrode is connected to another end of the resistor,
the second electrode is the anode of the light emission thyristor of each of the n pieces of switching elements,
the third electrode is the anode of the light emission thyristor of each of the plurality of light emitting elements,
the first control electrode is the N gate electrode of the light emission thyristor of each of the n pieces of the switching elements, and
the second control electrode is an N gate electrode of the light emission thyristor of each of the plurality of light emitting elements, and
(ii) when the anode is the common electrode,
a P gate electrode of the light emission thyristor of each of the n pieces of switching elements is connected to one end of the resistor,
the first electrode is connected to another end of the resistor,
the second electrode is the cathode of the light emission thyristor of each of n pieces of switching elements,
the third electrode is the cathode of the light emission thyristor of each of the plurality of light emitting elements,
the first control electrode is the P gate electrode of the light emission thyristor of each of the n pieces of switching elements, and
the second control electrode is a P gate electrode of the light emission thyristor of each of the plurality of light emitting elements;
a first driving circuit that is electrically connected to the first electrodes and that supplies the first signal;
a second driving circuit that is electrically connected to the second electrodes and that supplies the second signal; and
a third driving circuit that is electrically connected to the third signals and that supplies the third signal;
wherein the first driving circuit comprises a first signal level-setting portion that sets a potential at a high level and a low level of the first signal having a high level and a low level.

10. The light emitting device of claim 9, wherein the plurality of light emitting elements comprises a plurality of light emitting element blocks comprising n or less pieces of light emitting elements in which the third electrodes thereof are electrically connected to each other, and
the second control electrodes of the light emitting elements in one of the plurality of light emitting element blocks are connected to respective one of the n pieces of signal transmission lines which are different with each other.

11. The light emitting device of claim 10, wherein the plurality of light emitting elements are arranged in a line,
each of the plurality of light emitting element blocks is composed of n−1 pieces emitting elements (n is an integer of 4 or more),
odd-numbered light emitting elements blocks of the plurality of light emitting element blocks, which are numbered according to an order of from one end to the other end in an arrangement direction of the plurality of light emitting elements, each comprises an i₁-th light emitting element which is numbered according to the order of from one end to the other end in the arrangement direction, and the i₁-th light emitting is connected to a j₁-th signal transmission line so as to satisfy i₁=j₁ (wherein i₁ is an integer of 1 or more and n−1 or less and j₁ is an integer of 1 or more and n−1 or less), and
even-numbered light emitting element blocks of the light emitting element blocks, which are numbered according to an order of one end to the other end in the arrangement direction of the plurality of light emitting elements, each comprises an i₂-th light emitting element which is numbered according to the order of from one end to the other end in the arrangement direction, and the iᵢ-th light emitting is connected to j₂-th signal transmission line as to satisfy i₂+j₂=n+1 (wherein i₂ is an integer of 1 or more and n−1 or less and j₂ is an integer of 2 or more and n or less).

12. The light emitting device of claim 9, further comprising a substrate and bonding pads located on one surface of the substrate, wherein
the plurality of light emitting elements are arranged substantially in a straight line on the one surface of the substrate,
the n piece of signal transmission lines are located on the one surface of substrate along the arrangement direction of the plurality of light emitting elements,
the bonding pads are arranged at intervals therebetween along the arrangement direction of the plurality of light emitting elements,
the bonding pads comprises:
a first bonding pad connected to the first electrode;
second bonding pads connected to the respective second electrodes; and
third bonding pads connected to the third electrodes of the light emitting elements in respective ones of the plurality of light emitting element blocks and located in the light emitting element blocks, and a number of the third bonding pads being smaller than that of the plurality of light emitting elements, and
the n pieces of switching elements are located between the adjacent bonding pads.

13. The light emitting device of claim 9, wherein the second electrodes are respectively connected to the second resistors, and the second signal is applied to the second electrodes via the second resistors.

14. The light emitting device of claim 9, wherein the light emission thyristors of the n pieces of switching elements and the plurality of light emitting elements comprise the same layer structure.

15. The light emitting device of claim 9, further comprising a light-blocking portion or a light-reducing portion for blocking or reducing light emitted from the light emission thyristor of the switching element.

16. The light emitting device of claim 9, wherein the first signal level-setting portion comprises a plurality of resistors that are connected in series and that output a voltage for setting the potentials from a connecting portion connecting the plurality of resistors with each other.

17. An image forming apparatus, comprising:
the light emitting device of claim 8;
a light condensing portion configured for condensing light from the n pieces of light emitting elements the emitting device on a photoreceptor drum;
a developer supplying portion configured for supplying a developer to the exposed photoreceptor drum on which the light from the light emitting device is condensed by the light portion;
a transfer portion configured for transferring an image, formed on the photoreceptor drum by the developer onto a recording sheet; and
a fixing portion configured for fixing the developer transferred onto the recording sheet,
wherein the first, second and third driving circuits supply the first, second and third signals respectively, based on image information.
